(19) United States
(12) Patent Application Publication
(10) Pub. No.: US 2026/0040514 A1
(43) Pub. Date: Feb. 5, 2026

(54) COMPOSITE MATERIAL SYSTEM FOR REDUCTION OF PASSIVE INTERMODULATION

(71) Applicant: IsoTruss, Inc., Springville, UT (US)

(72) Inventors: Nathan D. Rich, Orem, UT (US); Evanston Vorwaller, Santaquin, UT (US); Marianne Clayton, Mountlake Terrace, WA (US); Anika Adams, Chapman, NE (US); Juan Ruiz, Santaquin, UT (US); Daniel Levine, Provo, UT (US)

(21) Appl. No.: 19/354,623

(22) Filed: Oct. 9, 2025

Related U.S. Application Data
(63) Continuation of application No. PCT/US2024/050941, filed on Oct. 11, 2024.
(60) Provisional application No. 63/589,569, filed on Oct. 11, 2023.
(60) Provisional application No. 63/682,919, filed on Aug. 14, 2024.

(51) Int. Cl. H05K 9/00; C08J 5/24; H04L 27/00

(52) U.S. Cl. CPC H05K 9/009; C08J 5/243; H04L 27/0012

(57) ABSTRACT

Mounting systems for telecommunications components include a shielding device that shields the components from the effects of passive intermodulation (PIM). The shielding devices can include a shielding panel or element made of a carbon fiber material that absorbs radio frequency interference, allowing the shielded component to clearly transmit and receive signals without interference due to PIM. The telecommunications tower can incorporate a composite material, such as a carbon fiber material or other non-corrosive material. The composite material can be incorporated into the frame and/or into mounting device providing for the mounting of components to the telecommunications tower, to mitigate the degradation, for example, in the form of corrosion, thus reducing or substantially eliminating sources of PIM.

### CROSS-REFERENCE TO RELATED APPLICATIONS

This application is a continuation of PCT Application No. PCT/US2024/050941, filed on Oct. 11, 2024, titled, “COMPOSITE MATERIAL SYSTEM FOR REDUCTION OF PASSIVE INTERMODULATION,” which claims priority to U.S. Provisional Application No. 63/682,919, filed on Aug. 14, 2024, titled “COMPOSITE MATERIAL SYSTEM FOR REDUCTION OF PASSIVE INTERMODULATION,” and to U.S. Provisional Application No. 63/589,569, filed on Oct. 11, 2023, titled “COMPOSITE MATERIAL SYSTEM FOR REDUCTION OF PASSIVE INTERMODULATION,” the disclosures of which are incorporated herein by reference in their entireties.

### FIELD

This document relates, generally, to structures including composite materials, and in particular, to structures including carbon fiber materials for the reduction or elimination of the effects of passive intermodulation (PIM).

### BACKGROUND

Telecommunications networks rely on the relay of radio signals to establish communication. These networks employ a plurality of towers, with various components coupled to the towers, to provide for the relay of radio signals. In some situations, passive intermodulation (PIM) can generate interference in the operation of these components and the relay of these radio signals. Sources of PIM can include, for example, corroded or rusted or otherwise degraded elements of the tower including, for example connectors, mounts, support members of the tower itself, and the like, improper and/or degraded mounting of components on the tower, degradation or damage in one or more of the components mounted on the tower, and other such sources.

### SUMMARY

Structures, in accordance with implementations described herein, incorporate composite materials. In some implementations, the composite material is a carbon fiber material. In some implementations, the composite material is incorporated into mounting devices, or coupling devices, or brackets, providing for coupling of various components to a frame of a three-dimensional (3D) frame or structure. In some implementations, the composite material is incorporated into support members of the frame or structure. In some implementations, the composite material is incorporated into the frame or structure, and also into at least some of the mounting devices, coupling devices, or brackets, providing for the mounting of components to the frame or structure. In some implementations, the frame or structure and the mounting devices, or coupling devices, or brackets, define a tower that provides for the relay of radio signals in a telecommunications network.

In some aspects, the techniques described herein relate to a device, including: a shielding member including a carbon fiber material, the shielding member being configured to be positioned proximate a component so as to shield the component from passive intermodulation (PIM) effects in an installation environment of the component.

In some aspects, the techniques described herein relate to a device, wherein the shielding member includes: a panel portion configured to be coupled to a corresponding coupling surface of the component; a first arm portion extending from a first lateral side portion of the panel portion, at an angle with respect to the panel portion, so as to shield a corresponding first lateral side portion of the component; and a second arm portion extending from a second lateral side portion of the panel portion, at an angle with respect to the panel portion, so as to shield a corresponding second lateral side portion of the component.

In some aspects, the techniques described herein relate to a device, wherein a contour of the panel portion, the first arm portion, and the second arm portion is at least partially conformal to a contour of the component, such that the panel portion, the first arm portion, and the second arm portion at least partially surround the component.

In some aspects, the techniques described herein relate to a device, further including: a plurality of openings formed in the panel portion and configured to receive coupling portions of the component therethrough.

In some aspects, the techniques described herein relate to a device, wherein the shielding member includes a plurality of shielding members configured to shield a respective plurality of components from PIM effects, each of the plurality of shielding members including: a panel portion configured to be coupled to a coupling surface of a component of the plurality of components; and at least one arm portion extending outward from a lateral side portion of the panel portion, at an angle with respect to the panel portion, so as to be positioned between the component and an adjacent component of the plurality of components.

In some aspects, the techniques described herein relate to a device, wherein the at least one arm portion includes: a first arm portion extending outward from a first lateral side portion of the panel portion, at an angle with respect to the panel portion, so as to be positioned between the component and a first adjacent component of the plurality of components; and a second arm portion extending outward from a second lateral side portion of the panel portion opposite the first lateral side portion thereof, at an angle with respect to the panel portion, so as to be positioned between the component and a second adjacent component of the plurality of components.

In some aspects, the techniques described herein relate to a device, wherein the device further includes: a first end plate; a second end plate; and a rod extending through the first end plate and the second end plate, wherein the plurality of shielding members and the plurality of components are positioned surrounding the rod, between the first end plate and the second end plate, and wherein the plurality of shielding members, the first end plate, and the second end plate define a plurality of receiving spaces respectively receiving the plurality of components.

In some aspects, the techniques described herein relate to a device, wherein the first end plate, the second end plate, and the plurality of shielding members are made of a carbon fiber composite material including a carbon fiber material impregnated in a resin material.

In some aspects, the techniques described herein relate to a device, wherein the shielding member includes: a panel portion configured to be coupled to a coupling surface of the component; and at least one portion configured to accommodate a bracket assembly coupling the component to a support structure.

In some aspects, the techniques described herein relate to a device, wherein the bracket assembly includes: a first bracket configured to be coupled to the coupling surface of the component; and a second bracket coupling the first bracket to a third bracket, wherein the second bracket and the third bracket are configured to couple the component to the support structure.

In some aspects, the techniques described herein relate to a device, wherein the first bracket includes: a first base wall configured to be coupled to the component; and first and second side walls extending outward from opposite end portions of the first base wall, toward the second bracket; and wherein the second bracket includes: a second base wall; first and second side walls extending outward from opposite end portions of the second base wall, toward the first bracket, wherein the first and second side walls of the second bracket are coupled to the first and second side walls of the first bracket; and first and second mating surfaces extending outward from upper and lower end portions of the second base wall, toward the third bracket; and wherein the third bracket includes: a third base wall; and first and second mating surfaces extending outward from upper and lower end portions of the third base wall, toward the second bracket, wherein the third base wall is adjustably couplable to the second base wall to adjust a distance between the first and second mating surfaces of the second bracket and the first and second mating surfaces of the third bracket, to couple the support structure between the second bracket and the third bracket.

In some aspects, the techniques described herein relate to a device, wherein the shielding member and the bracket assembly are made of a carbon fiber composite material including a carbon fiber material impregnated in a resin material.

In some aspects, the techniques described herein relate to a device, wherein the bracket assembly includes: a first bracket configured to be coupled to the coupling surface of the component; a second bracket configured to be coupled between the first bracket and the support structure, wherein the first bracket includes: a first base wall configured to be coupled to the component; and first and second side walls extending outward from opposite end portions of the first base wall, toward the second bracket; and wherein the second bracket includes: a second base wall; first and second side walls extending outward from opposite end portions of the second base wall, toward the first bracket; and first and second flange portions extending outward from the second base wall, the first and second flange portions being configured to be coupled to a second bracket of an adjacent bracket assembly coupling another component to the support structure, and to engage the support structure so as to couple the component to the support structure.

In some aspects, the techniques described herein relate to a device, wherein: the first bracket includes a first opening and a second opening in each of the first and second side walls of the first bracket; the second bracket includes a first opening in each of the first and second side walls of the second bracket, at positions corresponding to the first opening in each of the first and second side walls of the first bracket, so as to receive fasteners therethrough; and the second bracket includes a second opening, defined by an arcuate slot, formed in each of the first and second side walls of the second bracket, wherein fasteners are slidably received in the second openings in the first and second side walls of the second bracket, and coupled into the second openings in the first and second side walls of the first bracket, such that an angular orientation of the component relative to the support structure is adjustable based on a position of the fastener in the second openings in the first and second side walls of the second bracket.

In some aspects, the techniques described herein relate to a device, wherein the bracket assembly includes: a central bracket coupled to the support structure; a first arm rotatably coupled to a first end portion of the central bracket and configured to rotatably couple a first component to the support structure; and a second arm rotatably coupled to a second end portion of the central bracket and configured to rotatably couple a second component to the support structure, the first arm and the second arm each including: a body portion; a slot extending in a longitudinal direction of the body portion, the slot being configured to receive at least one fastener therethrough for coupling the body portion to respective component; and leg portions extending outward from upper and lower side portions of the body portion and configured to contact the respective component.

In some aspects, the techniques described herein relate to a device, wherein the component is a telecommunications component including at least one antenna configured to be mounted on a telecommunications tower, a telecommunications pole, or a mounting surface of a building.

In some aspects, the techniques described herein relate to a mounting system, including: a mounting device configured to mount a telecommunications component on a support structure; and a shielding member coupled to a coupling portion of the component, positioned between the component and the mounting device, wherein the shielding member is configured to shield the component from passive intermodulation (PIM) effects in an installation environment of the mounting structure.

In some aspects, the techniques described herein relate to a mounting system, wherein the shielding member includes: a panel portion configured to be coupled to a corresponding coupling surface of the component; a first arm portion extending from a first lateral side portion of the panel portion, at an angle with respect to the panel portion, so as to shield a corresponding first lateral side portion of the component; and a second arm portion extending from a second lateral side portion of the panel portion, at an angle with respect to the panel portion, such that a contour of the panel portion, the first arm portion, and the second arm portion is at least partially conformal to a contour of the component, and the first arm portion, and the second arm portion at least partially surround the component.

In some aspects, the techniques described herein relate to a mounting system, wherein the mounting device and the shielding member are made of a carbon fiber composite material including a carbon fiber material impregnated in a resin material.

In some aspects, the techniques described herein relate to a mounting system, wherein the mounting device includes a bracket assembly, including: a first bracket configured to be coupled to the component; a second bracket configured to be coupled between the first bracket and the support structure, wherein the first bracket includes a first side wall and a second side wall each including a first opening and a second opening, and the second bracket includes a first side wall and a second side wall each including a first opening and a second opening formed as an arcuate slot, and wherein fasteners are coupled in the first openings formed in the first and second side walls of the first and second brackets to couple the first and second side walls of the first and second brackets, and wherein fasteners are slidably received in the second openings in the first and second side walls of the second bracket, and coupled into the second openings in the first and second side walls of the first bracket, such that an angular orientation of the component relative to the support structure is adjustable based on a position of the fastener in the second openings in the first and second side walls of the second bracket.

In some aspects, the techniques described herein relate to a mounting system, wherein the mounting device includes a bracket assembly, including: a first bracket configured to be coupled to the component; a second bracket coupling the first bracket to a third bracket, wherein the support structure is received between the second bracket and the third bracket, wherein the second bracket includes first and second mating surfaces extending outward from upper and lower end portions of a base wall, toward the third bracket and wherein the third bracket includes first and second mating surfaces extending outward from upper and lower end portions of a base wall, toward the second bracket, with the support structure received between the respective mating surfaces of the first and second brackets, and wherein fasteners coupling the base wall of the third bracket and the base wall of the second bracket provide for adjustable coupling of the second and third brackets on the support structure.

In some aspects, the techniques described herein relate to a method, including: positioning a shielding member proximate a telecommunications component, the shielding member including a carbon fiber material; and shielding the component from effects of passive intermodulation (PIM) in an installation environment of the telecommunications component based on a placement position of the shielding member relative to a source of the PIM.

In some aspects, the techniques described herein relate to a method, wherein positioning the shielding member comprises attaching the shielding member to a surface of the telecommunications component such that PIM is prevented from interfering with signals processed by the telecommunications component.

In some aspects, the techniques described herein relate to a method, further comprising coupling the telecommunications component to a support structure with a bracket assembly, the bracket assembly including at least one bracket made of a carbon fiber composite material.

In some aspects, the techniques described herein relate to a method, wherein positioning the shielding member includes positioning the shielding member made of a carbon fiber composite material including a carbon fiber material impregnated in a resin material proximate the telecommunications component.

The details of one or more implementations are set forth in the accompanying drawings and the description below. Other features will be apparent from the description and drawings, and from the claims.

### BRIEF DESCRIPTION OF THE DRAWINGS

FIG. 1 is a perspective view of an example frame.

FIGS. 2A-2D are top views illustrating mounting of an example component to an example support structure, with example shielding devices mounted relative to the example component.

FIGS. 3A-3E illustrate an example shielding device.

FIGS. 4A-4C illustrate an example shielding device.

FIGS. 5A-5E illustrate an example shielding device.

FIGS. 6A-6C illustrate an example shielding device.

FIG. 7 illustrates a section of an example lattice telecommunications tower including an example mounting system.

FIGS. 8A and 8B illustrate a section of an example slim line telecommunications pole including an example mounting system.

FIG. 9 illustrates an example rooftop installation environment including example shielding members.

FIG. 10A is a first isometric view, and FIG. 10B is a second isometric view, of an example component mounting assembly including an example shielding device.

FIG. 10C is a first side view, and FIG. 10D is a second side view, of the example component mounting assembly and shielding device shown in FIGS. 10A and 10B.

FIG. 10E is a top view, and FIG. 10F is a bottom view, of the example component mounting assembly and shielding device shown in shown in FIGS. 10A-10D.

FIG. 11A is a first isometric view, FIG. 11B is a second isometric view, and FIG. 11C is a third isometric view, of the example component mounting assembly and shielding device shown in FIGS. 10A-10F, with a first end panel and a second end panel removed.

FIG. 11D is a top view of the example component mounting assembly and shielding device shown in FIGS. 11A-11C.

FIG. 12A illustrates an example slim line telecommunications pole incorporating an example component mounting assembly.

FIG. 12B illustrates the example slim line telecommunications pole shown in FIG. 12B, with a shroud removed.

FIG. 12C is a close in view of the example mounting assembly shown in FIG. 12A and 12B, illustrating a plurality of components mounted on the example mounting assembly.

FIG. 12D is a partially exploded view of the example arrangement shown in FIG. 12C.

FIG. 13A is a first isometric view, FIG. 13B is a second isometric view, and FIG. 13C is a side view, of a mounting portion the example mounting assembly shown in FIGS. 12A-12D.

FIG. 13D is top view, FIG. 13E is a first side view, and FIG. 13F is a second side view, of the mounting portion shown in FIGS. 13A-13C, removed from a rod of the example mounting assembly.

FIG. 14A is a top plan view, and FIG. 14B is an isometric top view, of the example mounting assembly shown in FIGS. 12A-12D.

FIG. 15A is an isometric view of an example component mounting assembly.

FIG. 15B is a top view of the example mounting assembly shown in FIG. 15A.

FIG. 15C is an exploded view of the example mounting assembly shown in FIGS. 15A and 15B.

FIG. 15D is a first perspective view, and FIG. 15E is a second perspective view, of the example mounting assembly shown in FIGS. 15A-15C, relative to one of the plurality of components.

FIG. 15F is a close-in view illustrating mounting of one of the plurality of components by the example mounting assembly shown in FIGS. 15A-15E, in a first orientation.

FIG. 15G is a close-in view illustrating mounting of one of the plurality of components by the example mounting assembly shown in FIGS. 15A-15E, in a second orientation.

FIG. 15H is a close-in view illustrating mounting of one of the plurality of components by the example mounting assembly shown in FIGS. 15A-15E, in a third orientation.

FIG. 16A illustrates an example component mounting assembly, including a plurality of components in a first arrangement.

FIG. 16B illustrates the example component mounting assembly shown in FIG. 16A, including the plurality of components in a second arrangement.

FIG. 17A is a first perspective view, and FIG. 17B is a second perspective view, of an example mounting assembly 1700 providing for the mounting of a component on a support structure.

FIG. 17C is an exploded view of the example mounting assembly shown in FIGS. 17A and 17B.

FIG. 17D is a perspective view of a bracket assembly of the example mounting assembly shown in FIGS. 17A-17C, removed from the component.

FIG. 17E is an exploded view of the example bracket assembly shown in FIG. 17D.

### DETAILED DESCRIPTION

Society is increasingly reliant on telecommunications networks in conducting commerce, providing for healthcare, education, emergency services, and many other sectors. Inconsistent or unreliable signal transmission can interrupt business/commerce, limit educational opportunities, degrade quality of life, and adversely impact the health and safety of communities. Telecommunications networks rely on the relay of radio signals between towers to establish communication. These networks typically employ a plurality of towers, with various components such as, for example, antennas, coupled to the towers, to provide for the relay of radio signals. In some situations, these towers and/or the components coupled thereto, experience passive intermodulation (PIM), which can adversely impact signal clarity.

In general, intermodulation is a secondary, disruptive signal, or distortion, caused when two or more primary signals pass through a non-linear device. Passive intermodulation (as opposed to active intermodulation) can be caused when a non-linear device is unpowered. This can be the result of, for example, degradation of portions of the tower, mounting device mounting components to the tower, and/or degradation of portions of the components themselves. For example, metal-on-metal connections throughout the tower and/or the mounting devices can, over time, degrade, or corrode, or rust, creating an oxidized layer that interferes with primary signals as well as the naturally occurring harmonics of the primary signals, generating distortion. In some situations, the distortion is amplified through the introduction of both additional signals and non-linear devices. Crowding of signals increases the amount of PIM, which can adversely impact receiving sensitivity, and can result in reduced reliability and/or capacity and/or data rates provided by these telecommunications systems. Unless the source of the PIM is identified and neutralized, the secondary signals will interfere with the primary signals, generating a baseline noise distortion. These distortions negatively affect the reliability and capacity of the network, which can result in loss of the primary signal.

Telecommunications networks have long experienced PIM, and the detrimental effects of PIM during operation, with no solution for eliminating PIM and/or efficiently and effectively mitigating the effect of PIM. Telecommunications networks have experienced an increased amount of PIM due to aging tower systems as the towers and/or the mounting devices mounting components to the towers corrode over time. Galvanizing the steel may slow the corrosion/degradation, but does not stop it, so signal disruption will continue to increase in response to continued degradation/rusting of the steel towers and/or mounting devices. This is further complicated by the continued expansion of 5G networks, which involve approximately ten times the tower density (compared to 4G networks) to maintain the signal. A significantly increased number, or volume, of towers needed to support 5G networks brings signals closer together, increasing interference between signals. As the spectrum becomes crowded, the opportunity for PIM to interfere with network signals increases. Additionally, newer network generations rely on a cleaner signal than their predecessors due to the higher order modulation of signals. What were considered acceptable levels of noise in a 4G network can impede the clarity of 5G signals. The expansion of 5G networks will drive a need for additional towers/greater number of components mounted thereon, with a greater number of towers/components having a higher possibility of mixed signals and/or increased amount of maintenance to address degradation/corrosion.

The longstanding process for isolating sources of PIM in a system has involved diagnostic testing, in which a PIM tester introduces a signal into an antenna circuit, and technicians monitor secondary signals to manually detect PIM. Once the presence of PIM is established, individual components in the circuit can be removed or blocked in an effort to isolate the source of PIM. While this diagnostic approach can be effective in confirming the occurrence of PIM, this approach often involves a somewhat random selection of components and/or areas of the tower in checking for PIM. This can be a time consuming and costly process, particularly as 5G networks expand and the number of towers increases accordingly. The development of systems that provide for earlier detection of PIM, and a more streamlined and/or targeted approach to detecting PIM, could alleviate some of this, to a certain extent. However, there has been a long-felt need for the development of systems that provide for mitigation or avoidance of the effects of PIM in the operation of components of these systems, and/or the elimination of sources of PIM.

In some examples, components, for example, antennas, are mounted further outward (for example, with respect to a vertical centerline of the tower), with the components spaced further apart and/or oriented at a greater radially separation, in an attempt to somewhat isolate the components from each other and thus reduce the effects of PIM. However, arrangement of components on the tower in this manner greatly reduces the number of components that can be mounted on the tower, thus reducing capacity, data rates, loads, and the like that can be provided by the tower. This solution becomes less viable when considering the additional resources required to support continually expanding 5G networks.

There is a long-felt need for a solution to PIM, both in reducing or substantially eliminating sources of PIM, and in shielding components from PIM, in these types of telecommunications systems, that has not been met by existing solutions. This long-felt need is exacerbated by the continued expansion of 5G networks and the continually growing need for additional telecommunications infrastructure and associated increased requirements for capacity, load, data rates, and the like.

Systems and methods, in accordance with implementations described herein, address the long-felt need for a solution to the issue of PIM, particularly as applied to telecommunications towers, and the effect of PIM on the operation and maintenance of components coupled to the telecommunications tower for the effective operation of a telecommunications network. Existing systems and methods have been ineffective in providing an efficient, expedient, affordable solution to the issue of PIM in the operation and maintenance of telecommunications towers. Existing systems and methods have been unable to provide a long term, efficient and effective solution to the problems associated with PIM in the operation and maintenance of telecommunications towers.

Systems and methods, in accordance with implementations described herein, include support structures, mounting systems, shielding systems, and the like that mitigate, or substantially eliminate, sources of PIM and/or the effects of PIM on the operation of components of a telecommunications tower, thus addressing the long-felt need for an efficient, effective long term solution to the problems generated by PIM in the operation of telecommunications towers, particularly as 5G networks continue to expand. Systems and methods, in accordance with implementations described herein, incorporate the use of composite material technology into these systems. Systems and methods, in accordance with implementations described herein, include tower elements, mounting system elements for mounting components on towers or other support structures, and shielding systems mounted at or near the support structures that provide shielding of components from PIM sources, to reduce or substantially eliminate the effects of PIM. Systems and methods, in accordance with implementations described herein, incorporate the use of composite material technology into these tower and component mounting and/or shielding systems. In some implementations, the component mounting systems include shielding devices incorporating composite material technology, providing for shielding from PIM for component(s) mounted on the mounting structure.

In some examples, the use of composite material in the tower reduces or substantially eliminates corrosion of elements of the tower that would otherwise be a potential source of PIM. In contrast to a steel communication tower, a tower made of composite material, for example, a carbon fiber material or other non-corrosive composite material, resists corrosion and the associated degradation. The lack of metal-to-metal connections between the composite material elements of the tower eliminates corrosion in these areas, thus eliminating a potential source of PIM. In some examples, the use of composite material, for example, a carbon fiber material embedded in, or impregnated in, a resin material, in mounting systems providing for the mounting components to a new or existing tower, or other mounting structure, similarly reduces or eliminates a potential source of PIM in the mounting system itself and/or in the connection of the mounting system to the tower or other support structure. In some examples, the mounting system includes a shielding device incorporating a composite material, for example, a carbon fiber material, that shields or isolates the component from the effects of PIM. In some examples, a shielding system incorporating a composite material, for example, a carbon fiber material, is mounted in the vicinity of the telecommunications components, proximate known or identified or potential sources of PIM, to shield the telecommunications components from PIM. Systems and methods, in accordance with implementations described herein, employ composite material, for example, carbon fiber material, to prevent signal distortion by directly eliminating potential sources of PIM and/or by effectively shielding the components from PIM, thus providing a preventative solution to PIM, rather than a reactive solution.

Testing was conducted to determine the effectiveness of composite material systems, for example, carbon fiber systems, as described herein, in reducing, or substantially eliminating the effects of PIM on components mounted on a support structure such as a telecommunications tower, a rooftop structure, and other such support structures. Carbon fiber shielding devices, in accordance with implementations described herein, include carbon fiber reinforced polymer materials including, for example, a plurality of strands of carbon fiber material embedded in, or impregnated in, a cured resin material. This results in a high strength, durable carbon fiber shielding device that can withstand detrimental environmental effects (i.e., weather conditions), and remain intact long term, while maintaining the original material properties that have been proved to be effective in the mitigation of the effects of PIM in these environments.

In an effort to establish the effectiveness of these carbon fiber material systems, a site having known harmful levels of PIM was identified. Source(s) of PIM, and the root cause(s) of PIM, at that site were also identified. Data was collected during a first test period, to establish a baseline performance profile of the system/components installed at the site, affected by the PIM. After collecting this data during the first test period, carbon fiber shielding devices, in accordance with implementations described herein, were installed at the site, at positions that provided for shielding of the various telecommunications components, such as antennas, at the site affected by the known/previously identified sources of PIM. Data was then collected during a second test period, in which the components were shielded from the known/previously identified sources of PIM by the carbon fiber shielding devices, in accordance with implementations described herein. The carbon fiber shielding devices were then removed, and testing was conducted during a third test period.

In this arrangement/environment, the components were rendered substantially inoperable during the first test period due to the effects of PIM. In this environment/arrangement, the system experienced a reduction in noise of between approximately 70% and 85% in the second test period, with the carbon fiber shielding devices installed, as compared to the first test period (prior to installation of the carbon fiber shielding devices), with the components regaining operability during the second test period. Noise levels in the third test period (after removal of the carbon fiber shielding devices) returned to the noise levels experienced during the first test period, with the components once again rendered inoperable due to the effects of PIM. In this environment/arrangement, the carbon fiber shielding devices were found to be RF absorbent, with the considerable reduction in noise during the second text period substantially wholly attributable to the introduction of the carbon fiber shielding devices, in accordance with implementations described herein. In an extension of this testing, panels made of a fiberglass material were similarly positioned so as to shield the components from the detrimental effects of PIM. In this arrangement, the fiberglass panels were found to be RF transparent. In this particular test arrangement, the panels made of the fiberglass material were not as effective in shielding the components from the detrimental effects of PIM, and maintaining the desired levels of operability of the components.

In one example scenario/arrangement of telecommunications components, approximately 20 dB of noise was consistently detected during the first test period and the third test period. In this same example scenario/arrangement of telecommunications components, a reduction of approximately 14 dB of noise was experienced during the second test period, this reduction being attributable to the installation of the carbon fiber shielding devices during this portion of the testing. In some example arrangements, every 3 dB reduction in noise represents a two-times (2×) improvement in RSSI (received signal strength indicator). Thus, the approximately 14 dB reduction in noise experienced during the second test period, attributable to the carbon fiber shielding devices, represents a considerable improvement in performance of the system of components installed on the support structure.

That is, in some examples, an approximately 6 dB increase in noise can reduce the effective footprint of an example telecommunications tower by approximately 50%. An approximately 9 dB increase in noise can reduce the effective footprint of the example telecommunications tower by approximately 65%. Accordingly, the approximately 14 dB reduction in noise experienced due to the installation of the carbon fiber shielding devices described above can significantly increase service footprint associated with a particular system installation/support structure, and also maintain that increased service footprint, even in the event of continued and/or increased levels of PIM.

In general, PIM is generated in an environment including a source that emits radio frequency waves, together with one or more connections involving dissimilar materials, and in particular, a connection involving dissimilar metal materials. Metal materials at opposite ends of the galvanic scale will generate greater levels of PIM than galvanically similar metal materials. Contact between the two (dissimilar) metal materials can create a diode that generates an interfering PIM signal. PIM signals generated within certain thresholds of a network site will interfere with network signals, adversely impacting network connectivity and/or range.

In some situations, PIM can be mitigated, or substantially eliminated, by reducing or eliminating these types of galvanically opposite connections. In some examples, this includes replacing degraded/rusty connections, replacing connectors including metal materials with insulating materials, and the like. In some examples, this includes reducing or substantially eliminating access to network signal components by the PIM sources, including, for example, shielding the network signal components from current and/or potential sources of PIM.

Using carbon fiber materials as a PIM shielding material, as PIM-mitigating/blocking fasteners and/or support structures, as PIM mitigating/blocking mounting and/or bracket assemblies, and/or so forth yielded unexpected results. As noted above, and as well documented in industry and scholarly literature, particularly related to PIM, it is well established that conductive materials (dissimilar metal materials or otherwise) generate PIM when introduced to a current in the vicinity of a signal generating/receiving component such as an antenna. Carbon fiber materials are generally known to be conductive, and thus would not have been expected to constitute a desirable material for use in the mitigation of PIM. The implementations of carbon fiber composite materials in these capacities (as mentioned above) thus yielded unexpected results.

In particular, it was unexpectedly discovered that carbon fiber to metal connections, although galvanically dissimilar, do not generate PIM, even though conventional thinking would have indicated that carbon fiber materials would exacerbate problems associated with PIM in providing for coupling typically involving metal to metal connection, and not reduce or substantially eliminate problems associated to PIM. Additionally, it was unexpectedly discovered that a carbon fiber shield can be positioned relative to a component to block PIM signals from interfering with the transmitting and receiving of signals by the component, even though, based on conventional thinking, such a carbon fiber shield should exacerbate the PIM signal, rather than blocking and/or mitigating the PIM signal. For at least these reasons, carbon fiber composite materials yield an unexpected result for use in PIM mitigation and/or blocking solutions.

It was unexpected that a material containing carbon fiber could be used to reduce PIM, because the literature on passive intermodulation broadly states that conductive materials are known to cause PIM when introduced to a current in the near vicinity of an antenna. Carbon fiber is generally known to be conductive, and would not be thought to constitute a desirable material for use in PIM mitigation solutions as a result. Additionally, in a passive system, PIM can be generated due to nonlinear materials such as carbon fiber composite materials or ferromagnetic materials. Accordingly, carbon fiber composites would be an unexpected material for effective use in providing PIM mitigation solutions.

Thus, the addition of carbon fiber shielding devices, in accordance with implementations described herein, may be incorporated into existing systems/existing support structures to regain performance previously lost due to PIM, thus regaining previously lost service footprint. Carbon fiber shielding devices, in accordance with implementations described herein, may allow an existing system to regain previously lost capacity, data rates, loads, and the like, without the need for extensive repair/replacement, installation of new support structures/new telecommunications components. Carbon fiber shielding devices, in accordance with implementations described herein, may allow more components to be more densely installed on a particular support structure due to the significantly reduced interference and resulting elimination of the effects of PIM on the operation of the components. Carbon fiber shielding devices, in accordance with implementations described herein, may facilitate the continued expansion of 5G networks, which rely on considerably higher tower density and a cleaner signal (compared to earlier generation networks). The example advantages provided by the incorporation of carbon fiber shielding devices into a system of telecommunications components, in accordance with implementations described herein, produce considerable cost savings to providers of telecommunications services, while also providing improved telecommunications services to the consumer.

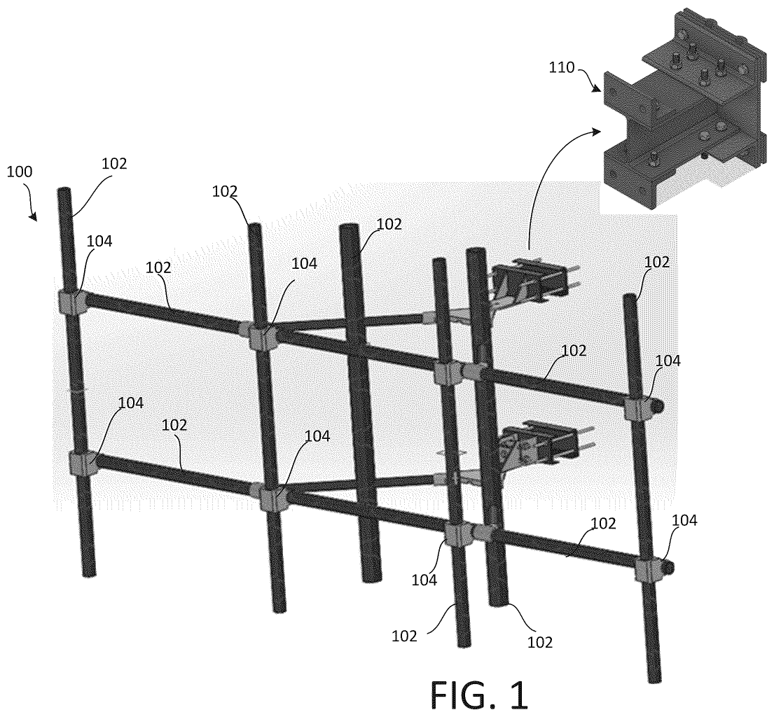

FIG. 1 is a perspective view of an example frame 100, showing a plurality of support members and connection members, arranged so as to eliminate metal to metal connections, thereby reducing or substantially eliminating potential sources of PIM. In some examples, the example frame 100 defines a sector of a telecommunications tower, or other support structure. In some examples, the example frame 100 is couplable to a telecommunications tower, or other support structure. In some examples, the example frame 100 forms a corresponding portion of a telecommunications tower or other support structure. In the example arrangement shown in FIG. 1, the example frame 100 includes a plurality of support members 102 coupled by a plurality of connection members 104. In some examples, the plurality of support members 102 are made of a composite material, such as a carbon fiber material or other non-corrosive composite material. In some examples, the plurality of support members 102 are made of another type of material. In some examples, the plurality of connection members 104 are made of a composite material, such as a carbon fiber material or other non-corrosive composite material. In some examples, the plurality of connection members 104 are made of another type of material such as, for example, a metal material, or another type of material. When made of steel, or other metal material, the connection of the plurality of support members 102 by the plurality of connection members 104 are a potential source of PIM. In contrast, a composite material, such as a carbon fiber material, is not subject to the rusting/degradation associated with a steel, or other metal material. Thus, an arrangement in which the support members 102 and/or the connection members 104 made of a composite material can substantially eliminate the frame 100 as a source of PIM. In some examples, the support members 102 are made of a composite material, and the connection members 104 are made of a metal material. In some examples, the support members and the connection members 104 are made of a composite material. In some examples, the support members 102 are made of a metal material and the connection members 104 are made of a composite material.

In the example arrangement shown in FIG. 1, an example mounting device 110 provides for the mounting of components to the example frame 100. In some examples, the mounting device 110 is made of a composite material, such as a carbon fiber material, or other non-corrosive composite material. When made of steel, or other metal material, this type of mounting device is a potential source of PIM, particularly if mounted to a support member 102 made of a meal material. In contrast, the example mounting device 110 made of a composite material is not subject to the rusting/degradation associated with a steel, or other metal material, and thus can substantially eliminate the mounting device 110 as a source of PIM.

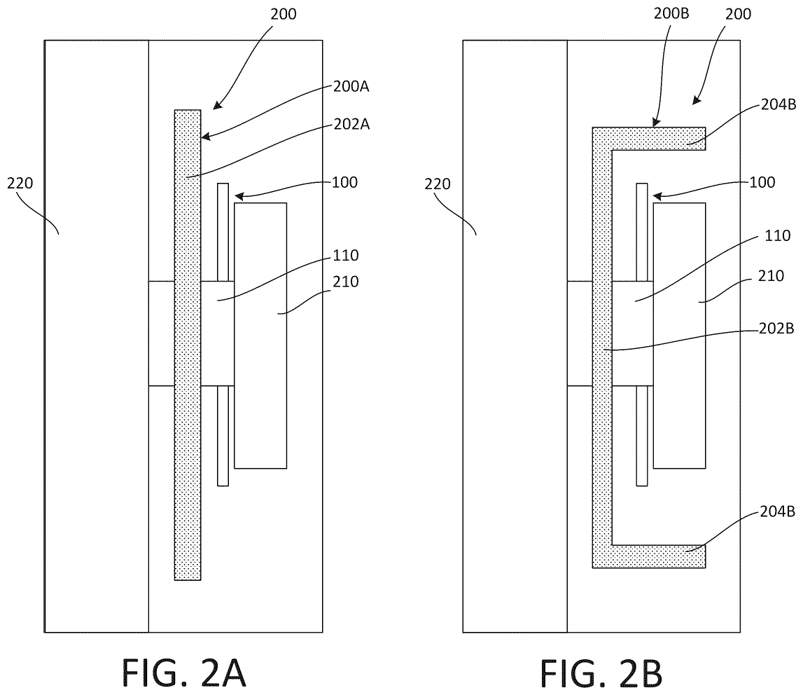

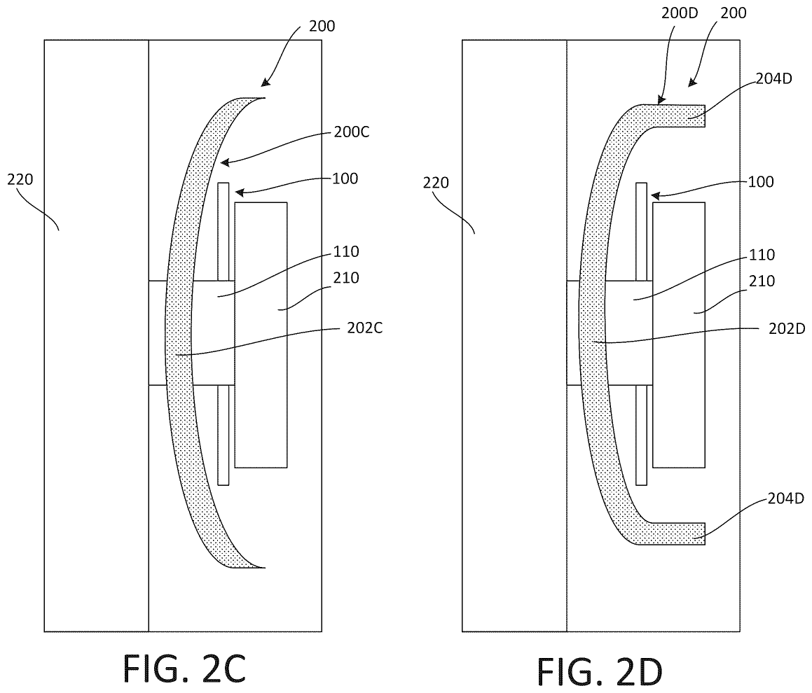

FIGS. 2A-2D are top views, illustrating the mounting of an example component 210, such as an antenna, to an example support structure 220, such as a telecommunications tower, or other structure to which telecommunications components are mounted. In some examples, the example component 210 is mounted at a sector of the example frame 100 shown in FIG. 1, by an example mounting system including a mounting device, such as the example mounting device 110 shown in FIG. 1, or other mounting device not explicitly shown herein. In the examples shown in FIGS. 2A-2D, a shielding device 200, in accordance with implementations described herein, partially surrounds a portion of the component 210. FIGS. 2A-2D illustrate various examples of potential geometries of the example shielding device 200, to provide for shielding of the component 210 from the effects of PIM. In particular, FIG. 2A is a top view illustrating an example shielding device 200A including a panel portion 202A having a substantially planar, or flat configuration. FIG. 2B is a top view illustrating an example shielding device 200B having a substantially planar, or flat panel portion 202B, with arm portions 204B provided at opposite lateral end portions of the panel portion 202B. In some examples, the arm portions 204B provide for additional shielding at lateral portions of the component 210. FIG. 2C is a top view illustrating an example shielding device 200C with a panel portion 202C having curved or arcuate configuration. FIG. 2D is a top view illustrating an example shielding device 200D having a curved panel portion 202D, with arm portions 204D provided at opposite lateral end portions of the panel portion 202D. In some examples, the arm portions 204D provide for additional shielding at lateral portions of the component 210. The example shielding devices 200 shown in FIGS. 2A-2D are provided for purposes of discussion and illustration. The principles described herein are applicable to shielding devices having different configurations and/or features and or combinations thereof than explicitly shown herein.

The shielding device 200 is made of a composite material, such as a carbon fiber material. The shielding device 200, made of the carbon fiber material, shields the component 210 from the effects of PIM, allowing the component 210 to transmit and receive signals without noise or interference due to PIM. In some examples, the shielding device 200 made of the carbon fiber material shields the component 210 from the effects of PIM, regardless of the composition of the support structure 220 and/or the frame 100 and/or the mounting device 110. In some examples, the shielding device 200 made of the carbon fiber material shields the component 210 from the effects of PIM, even when the PIM is generated at one or more of the support structure 220 and/or the frame 100 and/or the mounting device 110.

As described above, during testing, carbon fiber shielding devices, for example, in the form of panels or other configurations, were positioned proximate sources of PIM and/or proximate components such as antennas. The carbon fiber shielding devices were found to isolate, or shield, the antennas from the effects of PIM, allowing the antennas to clearly and consistently transmit and receive radio frequency (RF) signals. When the carbon fiber shielding devices were removed, these same antennas were rendered inoperable under the same operating conditions due to the effects of PIM. When the carbon fiber shielding devices were replaced with shielding panels made of other materials, testing indicated that the shielding panels made of these alternate materials were ineffective in shielding the antennas from the detrimental effects of PIM, and these same antennas were once again rendered inoperable under the same operating conditions due to the effects of PIM. This testing yielded unexpected results, in the high degree of isolation or shielding from the effects of PIM provided by the carbon fiber shielding devices. These results are that much more unexpected given that the panels made of other materials provided little to no isolation from the effects of PIM. Thus, it was found that the carbon fiber material used in the carbon fiber shielding panels possesses unexpected radio absorbent properties (that other materials do not possess). The radio absorbent properties of the carbon fiber material in these shielding panels provide for the isolation, or shielding of the antennas from the noise and/or interference due to PIM that would otherwise significantly affect the efficient and effective operation of the antennas. These unexpected results thus address the long-felt need for a way to mitigate the effects of PIM and/or reduce or substantially eliminate the sources of PIM in the operation of components of a telecommunications system.

The shielding of the antennas provided by the example carbon fiber shielding device 200 described above allows the antennas to clearly and consistently transmit and receive radio frequency (RF) signals, thus maintaining the efficient and effective operation of the antennas mounted on a telecommunications tower, or other mounting structure. The shielding of the antennas provided by the example carbon fiber shielding device 200 described above allows the antennas to clearly and consistently transmit and receive radio frequency (RF) signals even in an environment in which disturbances may be generated due to PIM in surrounding structures such as, for example, mounting devices mounting the antennas to the support structure and/or the support structure itself.

The shielding of the antennas provided by the example carbon fiber shielding device 200 described above may allow for components such as antennas to be more densely arranged on existing support structures, such as, for example, telecommunications towers, while still clearly and consistently transmitting and receiving RF signals. That is, as noted above, in some situations, in an attempt to reduce interference, components have been moved outward, and spaced further apart on telecommunications towers, greatly reducing the number of components that can be mounted on a tower, and reducing capacity, data rates, loads, and the like that can be provided by the tower. The use of a shielding device, such as the example carbon fiber shielding device 200 described above, allows the components, including, for example, antennas, to be brought back in, closer to the mounting structure, i.e., the telecommunications tower in this example, and to be more densely arranged on the support structure. This is beneficial in that it will allow the tower to provide increased capacity, data rates, loads and the like, and is particularly beneficial as 5G networks continue to expand.

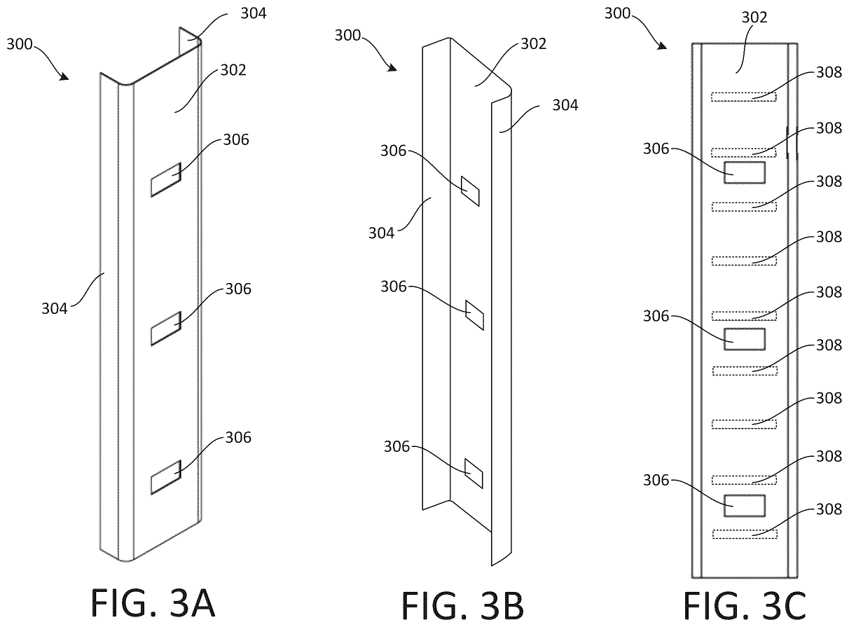

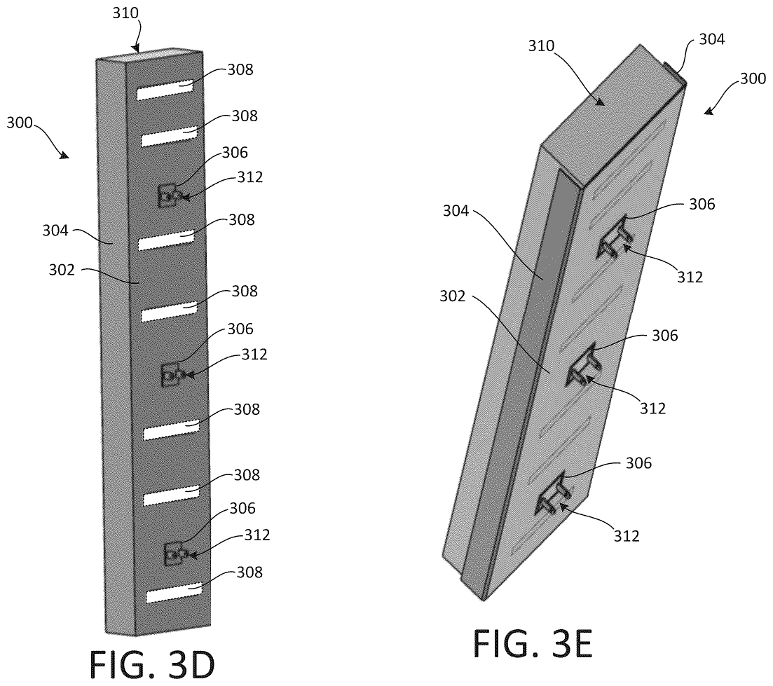

FIGS. 3A-3E illustrate an example shielding device 300, in accordance with implementations described herein. The example shielding device 300, or a blocking device, can be coupled to a component such as, for example, an antenna, to block, or shield the component from the effects of PIM. In some examples, the example shielding device 300 is made of a composite material, such as a carbon fiber material, that provides for the shielding, or blocking of the component from the effects of PIM. In some examples, a contour of the example shielding device 300 corresponds to a contour of the example component 310. In particular, FIG. 3A is a first perspective view, FIG. 3B is a second perspective view, and FIG. 3C is a front view, of the example shielding device 300. FIG. 3D is a first perspective view, and FIG. 3E is a second perspective view, of the example shielding device 300 coupled to an example component 310. In the example shown in FIGS. 3D and 3E, the example component 310 is an antenna array, including a plurality of coupling portions 312 to which a corresponding plurality of antennas can be coupled.

The example shielding device 300 shown in FIGS. 3A-3E includes a panel portion 302 and arm portions 304 at opposite lateral sides of the panel portion 302. In the example arrangement shown in FIGS. 3D and 3E, the arm portions 304 extend around corresponding lateral side portions of the component 310, simply for purposes of discussion and illustration. The principles described herein are applicable to the fitting of the example shielding device to other components having different physical configurations. In the example arrangement, a contour of the shielding device 300 including the panel portion 302 and arm portions 304 corresponds to a contour of the component 310 to which it is coupled, such that the contour of the shielding device 300 is at least partially conformal to the contour of the component 310 to which it is coupled. In the example arrangement shown in FIGS. 3A-3E, the example shielding device 300 includes a plurality of openings 306 formed in the panel portion 302. The plurality of openings 306 allow for a corresponding plurality of coupling portions 312 of the component 310, to pass therethrough, so that a plurality of antennas (not shown in FIGS. 3A-3E) can be coupled thereto. The example shielding device 300 can include more, or fewer openings 306, arranged similarly to or differently from the example plurality of openings 306 as shown. In some examples, a plurality of coupling areas 308 are defined on the example shielding device 300. In this example arrangement, the plurality of coupling areas 308 are defined on the panel portion 302 of the example shielding device 300. In some examples, the plurality of coupling areas 308 provide for the coupling of the shielding device 300 to the component 310. In some examples, the plurality of coupling areas 308 define adhesion areas, where the component 310 can be adhered to the shielding device 300. In some examples, the component 310 is coupled to the shielding device 300 in other ways.

The example shielding device 300 incorporates composite material, and in particular, carbon fiber material, to provide for blocking shielding of the component 310 from the effects of PIM. In some examples, both the panel portion 302 and the arm portions 304 of the shielding device 300 are made of carbon fiber material. In some examples, the panel portion 302 of the shielding device 300 is made of carbon fiber material. The example shielding device 300 can be adapted to fit a variety of different sizes and/or shapes and/or configurations of antenna arrays and/or types, to provide for the desired blocking or shielding of the antenna array from the effects of PIM.

In the example described above, the example shielding device 300 is coupled to a telecommunications component, such as an antenna, for purposes of discussion and illustration. In some examples, the panel portion 302 and/or the arm portions 304 may be incorporated into the fabrication of the telecommunications component. For example, a panel portion and/or arm portions including carbon fiber material may form a portion of a housing of the component itself, for example, a portion of the housing of the component that would provide for shielding of the component from the effects of PIM in that area/portion of the component, and/or surrounding components.

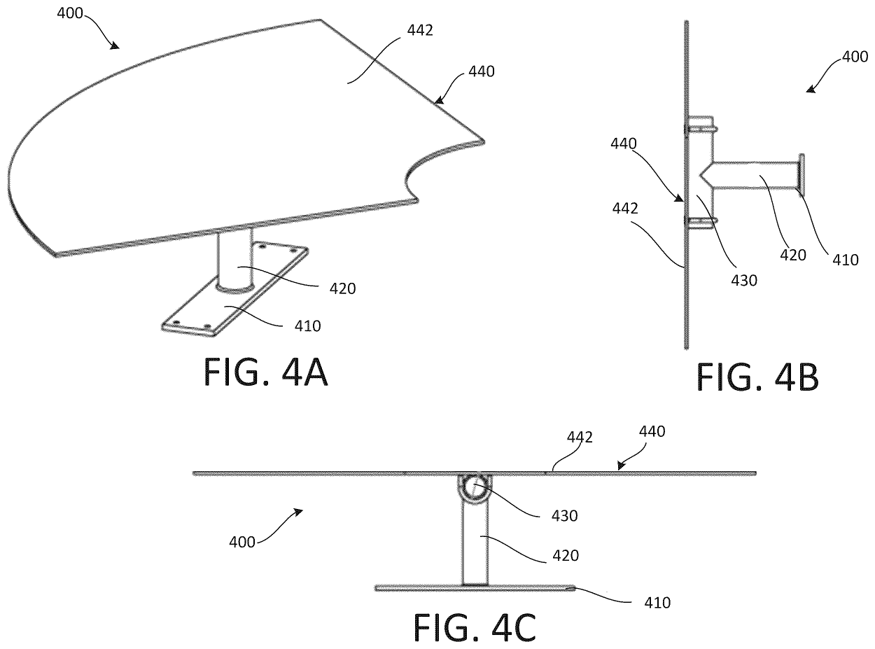

FIGS. 4A-4C illustrate an example shielding device 400, in accordance with implementations described herein. The example shielding device 400 may include all composite components, or a combination of composite components and metal components that avoid metal to metal connections, thus reducing or substantially eliminating potential sources of PIM. In particular, FIG. 4A is a perspective view, FIG. 4B is a first side view, and FIG. 4C is a second side view, of the example shielding device 400. In some examples, the example shielding device 400 can be installed in proximity of one or more components relying on shielding from the effects of PIM. In some examples, components can be coupled to, or on, the example shielding device 400 to provide for the desired shielding from the effects of PIM. In some examples, the example shielding device 400 can be otherwise positioned relative to one or more components relying on shielding from the effects of PIM so as to intercept signals which may otherwise interfere with operability of the one or more components. In some examples, the example shielding device 400 is mounted to a mounting structure in the form of a rooftop or other building structure. In some examples, the example shielding device 400 is mounted to or in proximity of another type of structure to which telecommunications components relying on shielding are mounted, such as, for example, a telecommunications tower.

The example shielding device 400 shown in FIGS. 4A-4C includes a mounting plate 410 configured to be coupled to or mounted on the mounting structure. A mounting arm 420 extends outward from the mounting plate 410 to a support member 430. A shielding member 440 is coupled on the support member 430. The shielding member 440 is made of a carbon fiber material, so that the shielding member 440 can provide for blocking of RF signals, or shielding of a telecommunications component such as an antenna, from interference. In some examples, the shielding device 400 is incorporated into an arrangement of telecommunications components such that a shielding surface 442 of the shielding member 440 is positioned, or oriented to shield one or more of the components from the effects of PIM, and from signals that would interfere with the operability of the one or more components. The example shielding member 440 shown in FIGS. 4A-4C has a substantially planar configuration, simply for purposes of discussion and illustration. The principles described herein are applicable to shielding members having other shapes and/or configurations and/or contours. FIG. 4B illustrates a substantially vertical installation (in the example orientation shown in FIGS. 4A-4C) of the example shielding device 400, and FIG. 4C illustrates a substantially horizontal installation (in the example orientation shown in FIGS. 4A-4C) of the example shielding device 400, simply for purposes of discussion and illustration. The principles described herein are applicable to installations of the example shielding device 400 in which a surface or structure to which the example shielding device 400 is mounted is oriented differently than shown, such that the shielding provided by the shielding device 400 can be varied based on the placement of the various telecommunications components to be shielded, mounting surfaces and/or structures available for mounting of the shielding device 400, and the like.

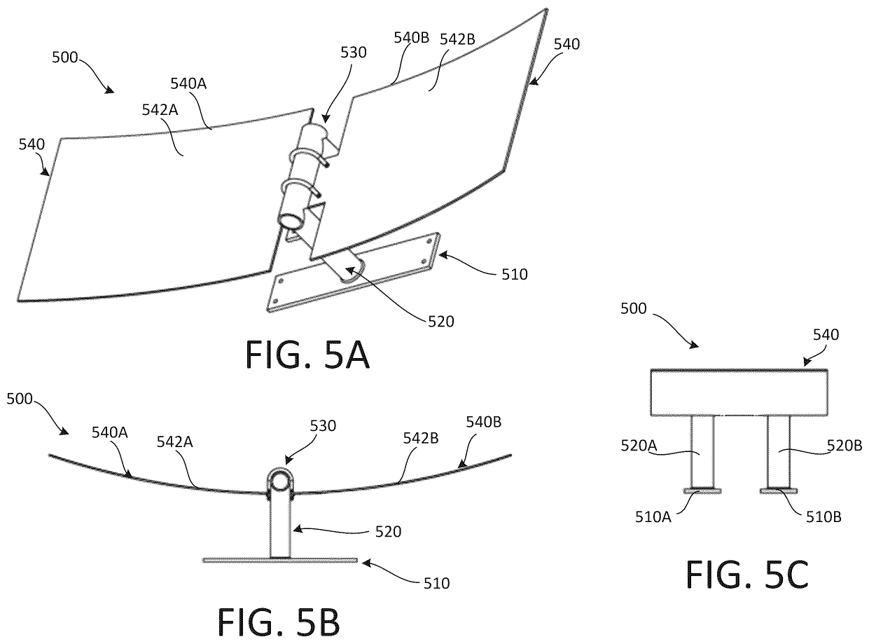

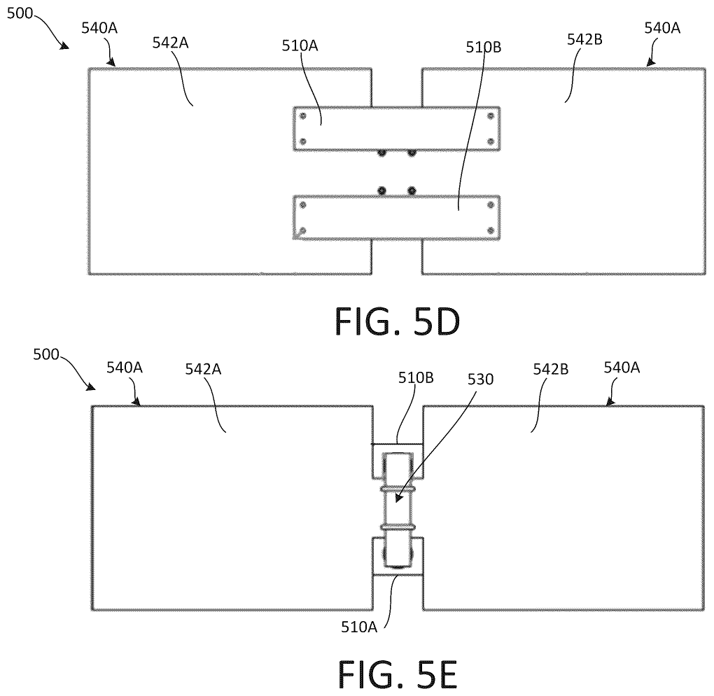

FIGS. 5A-5E illustrate an example shielding device 500, in accordance with implementations described herein. The example shielding device 500 may include all composite components, or a combination of composite components and metal components that avoid metal to metal connections, thus reducing or substantially eliminating potential sources of PIM. In particular, FIG. 5A is a perspective view, FIG. 5B is a first side view, and FIG. 5C is a second side view, of the example shielding device 500. FIG. 5D is a bottom, or rear view of the example shielding device 500. FIG. 5E is a top, or front view of the example shielding device 500. In some examples, the example shielding device 500 can be installed in proximity of one or more components relying on shielding from the effects of PIM. In some examples, components can be coupled to, or on, the example shielding device 500 to provide for the desired shielding from the effects of PIM. In some examples, the example shielding device 500 can be otherwise positioned relative to one or more components relying on shielding from the effects of PIM so as to intercept signals which may otherwise interfere with operability of the one or more components. In some examples, the example shielding device 500 is mounted to a mounting structure in the form of a rooftop or other building structure. In some examples, the example shielding device 500 is mounted to or in proximity of another type of structure to which telecommunications components relying on shielding are mounted, such as, for example, a telecommunications tower.

The example shielding device 500 includes at least one mounting plate 510 configured to be coupled to or mounted on the mounting structure. The example shielding device 500 shown in FIGS. 5A-5E includes a first mounting plate 510A and a second mounting plate 510B. At least one mounting arm 520 extends outward from the at least one mounting plate 510 to a support member 530. The example shielding device 500 shown in FIGS. 5A-5E includes a first mounting arm 520A and a second mounting arm 520B. At least one shielding member 540 is coupled on the support member 530. The example shielding device 500 shown in FIGS. 5A-5E includes a first shielding member 540A and a second shielding member 540B. The shielding member 540, i.e., the first shielding member 540A and the second shielding member 540B, is made of a carbon fiber material, so that the shielding member 540 can provide for blocking of RF signals, or shielding of a telecommunications component such as an antenna, from interference. In some examples, the shielding device 500 is incorporated into an arrangement of telecommunications components such that shielding surfaces of the shielding members 540 (i.e., a first shielding surface 542A provided by the first shielding member 540 and a second shielding surface 542B provided by the second shielding member 540B) are positioned, or oriented to shield one or more of the components from the effects of PIM, and from signals that would interfere with the operability of the one or more components. The principles described herein are applicable to installations of the example shielding device 500 in which a surface or structure to which the example shielding device 500 is mounted is oriented at a plurality of different orientations, such that the shielding provided by the shielding device 500 can be varied based on the placement of the various telecommunications components to be shielded, mounting surfaces and/or structures available for mounting of the shielding device 500, and the like.

In some examples, the support member 530 provides for adjustment of a position of at least one of the first shielding member 540A or the second shielding member 540B. For example, the support member 530 may provide for rotation of one of the first shielding member 540A or the second shielding member 540B relative to the other of the first shielding member 540A or the second shielding member 540B. In some examples, the first shielding member 540A and the second shielding member 540B may be independently rotatable relative to the support member 530. This may provide for further variability of the placement and orientation of shielding surfaces 542 (i.e., the first shielding surface 542A and the second shielding surface 542B) of the shielding members 540 (i.e., the first shielding member 540A and the second shielding member 540B) based on the placement of the various telecommunications components to be shielded, mounting surfaces and/or structures available for mounting of the shielding device 500, and the like.

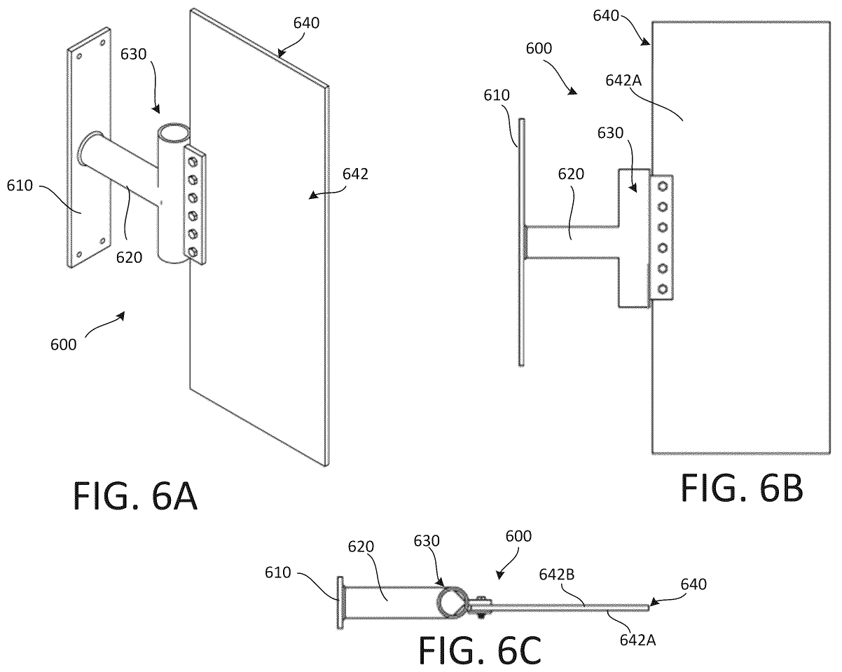

FIGS. 6A-6C illustrate an example shielding device 600, in accordance with implementations described herein. The example shielding device 600 may include all composite components, or a combination of composite components and metal components that avoid metal to metal connections, thus reducing or substantially eliminating potential sources of PIM. In particular, FIG. 6A is a perspective view of the example shielding device 600. FIG. 6B is a first side view, and FIG. 6C is a second side view, of the example shielding device 600. In some examples, the example shielding device 600 can be installed in proximity of one or more components relying on shielding from the effects of PIM. In some examples, components can be coupled to, or on, the example shielding device 600 to provide for the desired shielding from the effects of PIM. In some examples, the example shielding device 600 can be otherwise positioned relative to one or more components relying on shielding from the effects of PIM so as to intercept signals which may otherwise interfere with operability of the one or more components. In some examples, the example shielding device 600 is mounted to a mounting structure in the form of a rooftop or other building structure. In some examples, the example shielding device 600 is mounted to or in proximity of another type of structure to which telecommunications components relying on shielding are mounted, such as, for example, a telecommunications tower.

The example shielding device 600 includes a mounting plate 610 configured to be coupled to or mounted on the mounting structure. A mounting arm 620 extends outward from the mounting plate 610 to a support member 630. A shielding member 640 is coupled on the support member 630. The shielding member 640 is made of a carbon fiber material, so that the shielding member 640 can provide for blocking of RF signals, or shielding of a telecommunications component such as an antenna, from interference. In some examples, the shielding device 600 is incorporated into an arrangement of telecommunications components such that shielding surfaces 642 of the shielding member 640 are positioned, or oriented to shield multiple components from the effects of PIM, and from signals that would interfere with the operability of the components. The example shielding member 640 shown in FIGS. 6A-6C has a substantially planar configuration, simply for purposes of discussion and illustration. The principles described herein are applicable to shielding members having other shapes and/or configurations and/or contours. FIG. 6B illustrates a substantially vertical orientation of the example shielding device 600, and FIG. 6C illustrates a substantially horizontal orientation of the example shielding device 600, simply for purposes of discussion and illustration. The principles described herein are applicable to installations of the example shielding device 600 in which a surface or structure different orientations, such that shielding provided by the shielding surfaces 642 of the shielding device 600 can be varied based on the placement of the various telecommunications components to be shielded, mounting surfaces and/or structures available for mounting of the shielding device 600, and the like.

In the example shown in FIGS. 6A-6C, the shielding member 640 of the example shielding device 600 includes a first shielding surface 642A and a second shielding surface 642B. The shielding member 640 of the shielding device 600 can be positioned between adjacent components of the telecommunications system, such that the shielding member 640 can provide for shielding of components from multiple sides of the shielding member 640, i.e., at the first shielding surface 642A and the second shielding surface 642B of the shielding member 640. The shielding provided by the shielding member 640 of the example shielding device 600 may allow for components of the telecommunications system to be positioned more closely together on the mounting structure (i.e., a telecommunications system, a roof mounted system, or other such mounting structure). The shielding provided by the shielding device 600 in this manner may allow for increased component density, and increased system capacity and/or loads and/or data rates.

In some examples, the support member 630 provides for adjustment, for example, rotatable adjustment, of a position of the shielding member 640 relative to the support member 630. This may provide for further variability of the placement and orientation of first shielding surface 642A and the second shielding surface 642B of the shielding device 600 based on the placement of the various telecommunications components to be shielded, mounting surfaces and/or structures available for mounting of the shielding device 600, and the like.

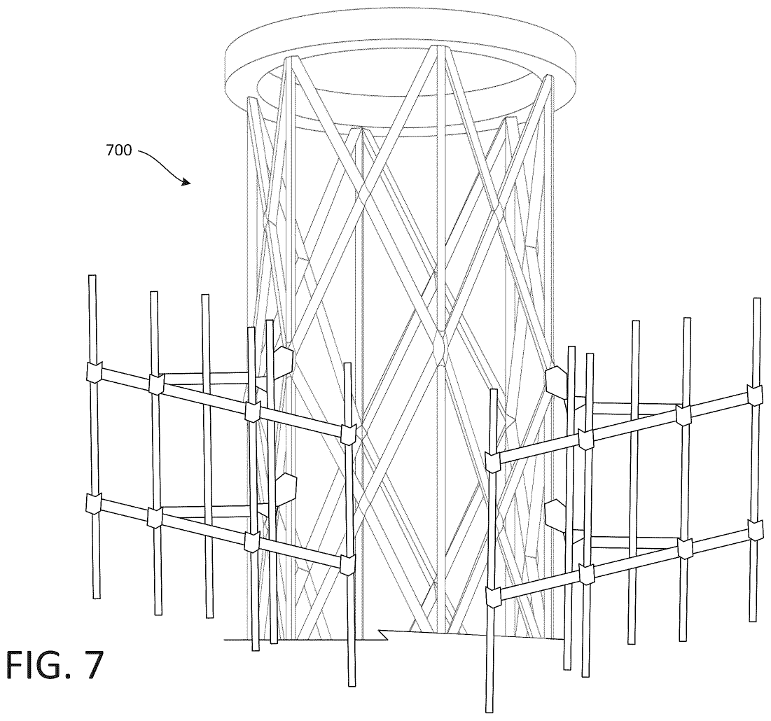

FIG. 7 illustrates a section of a three-dimensional load bearing structure, defining a lattice type telecommunications tower 700. In some examples, an auxiliary frame, such as the example frame 100 shown in FIG. 1, or another such frame, can be coupled to the tower 700. In some examples, the lattice structure of the tower is a conventional stainless steel structure. In some examples, the lattice structure of the tower is defined by a three-dimensional IsoTruss structure. In some examples, the IsoTruss structure includes a plurality of longitudinal members extending along a longitudinal length of the IsoTruss structure. In some examples, a plurality of helical structures, defined by a plurality of transverse members arranged end to end, are coupled to the plurality of longitudinal members at a plurality of nodes. In some examples, the plurality of longitudinal members are defined by a plurality of strands of carbon fiber material embedded in, or impregnated in, a resin material. In some examples, the plurality of helical members are defined by a plurality of strands of carbon fiber material embedded in, or impregnated in, a resin material. In some examples, the plurality of strands of the carbon fiber material of the longitudinal members and the plurality of strands of the carbon fiber material of the helical members are interwoven at the plurality of nodes. Additional information related to such a three-dimensional load bearing structure is provided in commonly owned U.S. Pat. No. 10,557,267, which is incorporated by reference herein in its entirety.

Telecommunications equipment, including components such as, for example, antennas and the like, can be coupled to the lattice structure of the tower itself, and/or to the auxiliary frame, as described above. In some examples, the carbon fiber structure of the tower itself may eliminate sources of PIM that would be generated by the tower, by eliminating metal to metal connections that become sources of PIM over time. Any of the shielding devices described above with respect to FIGS. 2A-6C can be coupled to the structure of the tower and/or to the auxiliary frame, to provide for shielding of components coupled to the tower (directly or indirectly, via the auxiliary frame) from the detrimental effects of PIM.

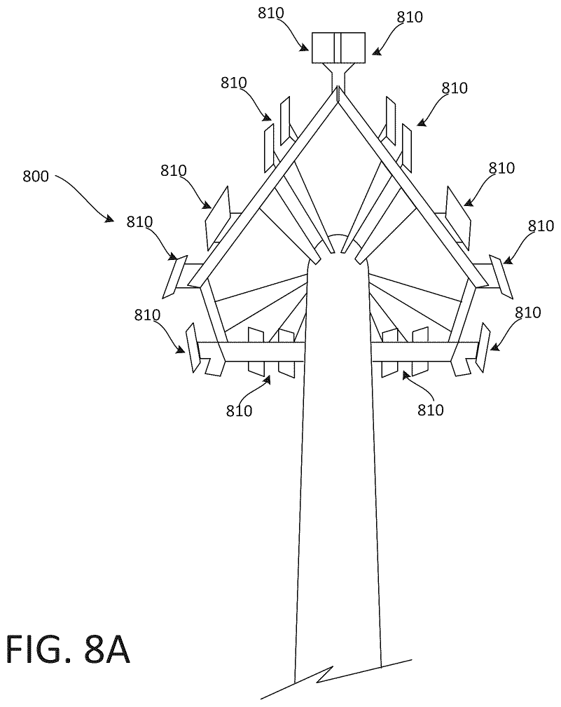

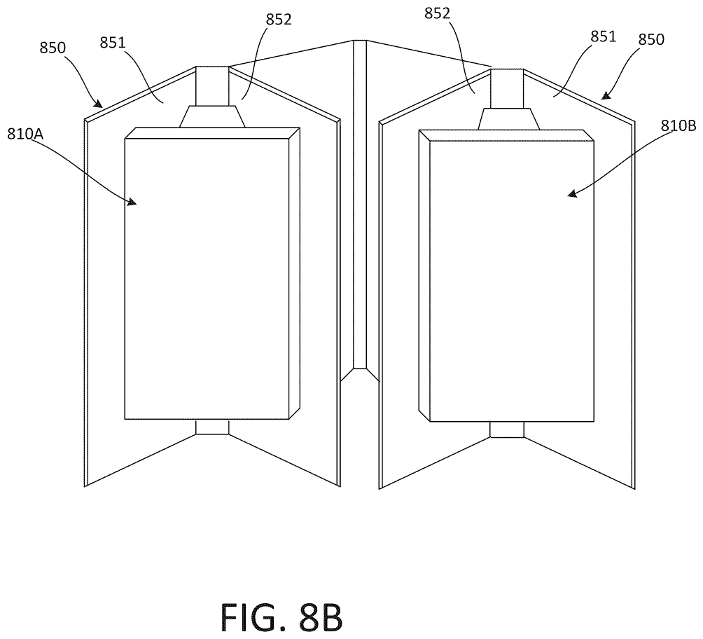

FIG. 8A is a bottom perspective view of a monopole tower, or a slim line telecommunications pole 800, to which telecommunications equipment 810 including components such as, for example, antennas and the like, can be coupled. Monopole towers, or slim line telecommunications poles, are installed in installation environments in which installation space is limited, zoning regulations limit the size of equipment, and the like. In this type of arrangement, equipment 810, i.e., antennas, tend to be positioned in relatively close proximity to each other, due to the smaller profile of the slim line telecommunications pole 800. As shown in FIG. 8B, in some examples, carbon fiber shielding devices 850, in accordance with implementations, may be positioned relative to adjacent first and second antennas 810A, 810B to provide for shielding between the first antenna 810A and the second antenna 810B, and eliminate interference due to the proximity of the adjacent first and second antennas 810A, 810B. In the example shown in FIG. 8B, each shielding device 850 includes a first carbon fiber panel 851 and a second carbon fiber panel 852, providing for RF shielding between the first antenna 810A and the second antenna 810B, and allowing for the first antenna 810A and the second antenna 810B to maintain operability while positioned in close proximity to each other on the slim line telecommunications pole 800.

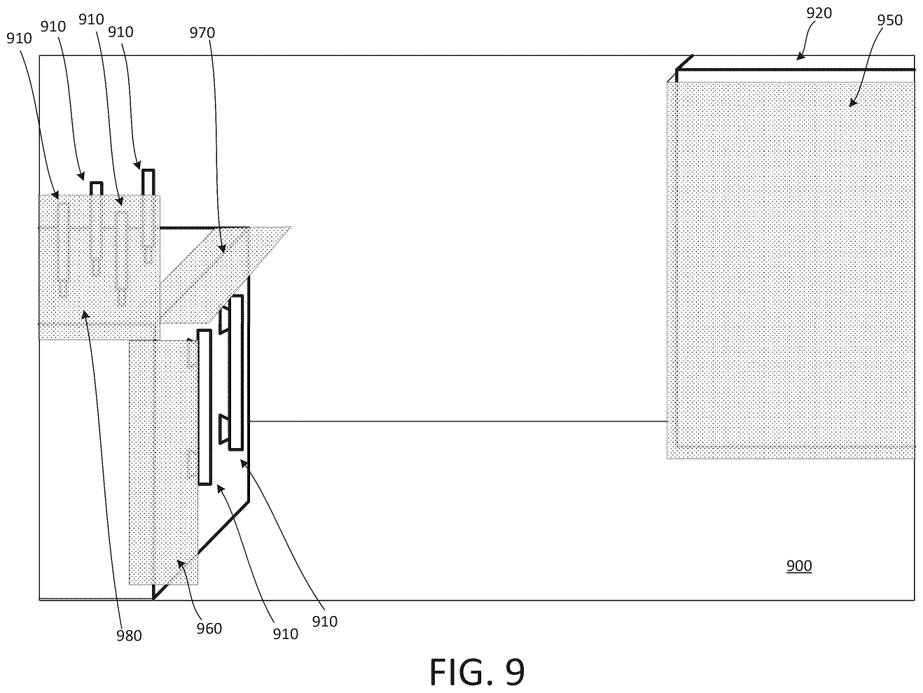

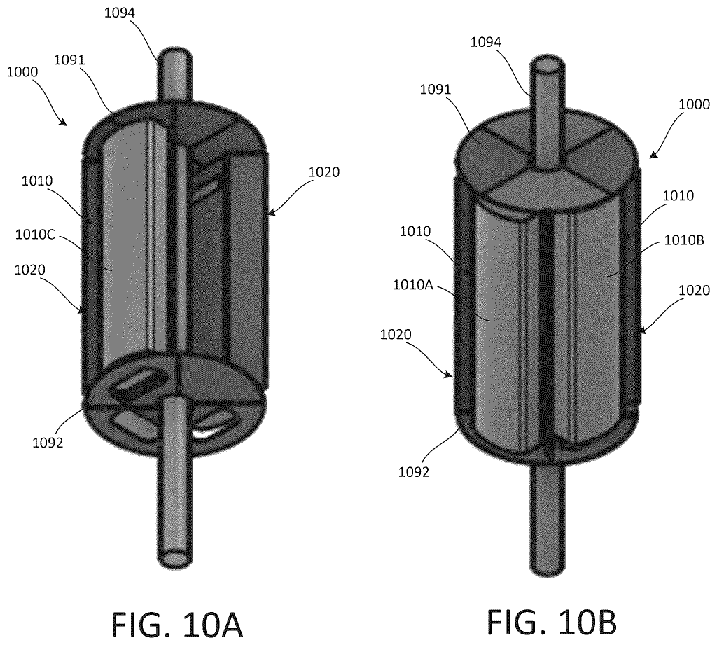

FIG. 9 illustrates a rooftop, or building 900 defining an installation environment in which telecommunications equipment 910 including components such as, for example, antennas and the like, can be installed. In the example shown in FIG. 9, an example carbon fiber shielding device 950 is positioned corresponding to a previously identified source 920 of PIM, to shield the telecommunications equipment 910 from PIM generated by the previously identified source 920. In the example shown in FIG. 9, various example shielding devices 960, 970, 980 are arranged relative to the telecommunications equipment 910, to provide for shielding of the telecommunications equipment 910 from other sources of PIM (not explicitly identified in FIG. 9) and/or interference amongst the various components. The example shielding devices 950, 960, 970, 980 are provided in FIG. 9 simply for purposes of discussion and illustration. Carbon fiber shielding devices, in accordance with implementations described herein, can be configured and adapted to provide for shielding of any number and/or combinations of components.

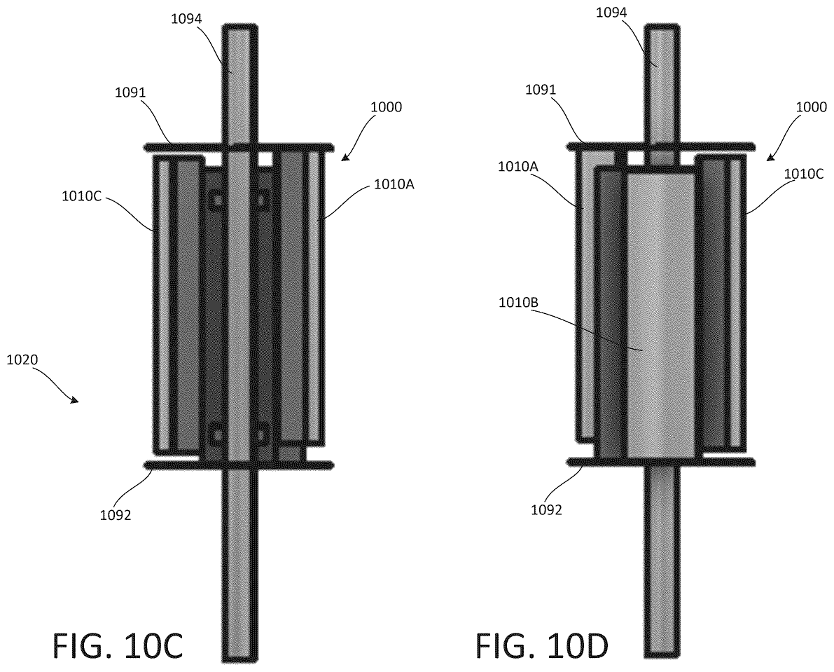

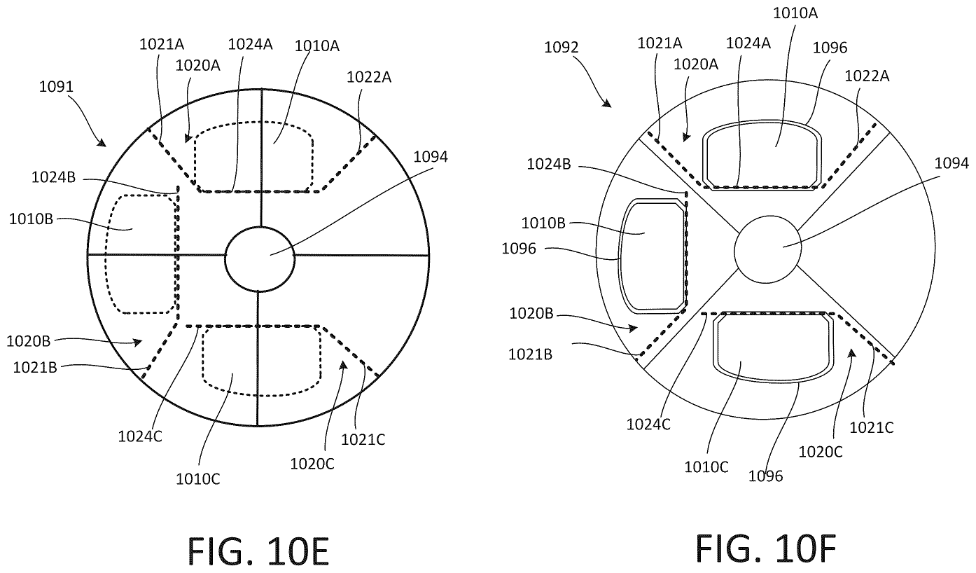

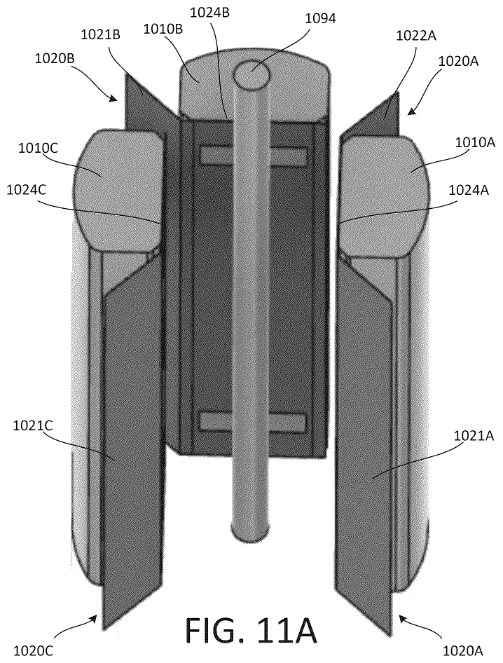

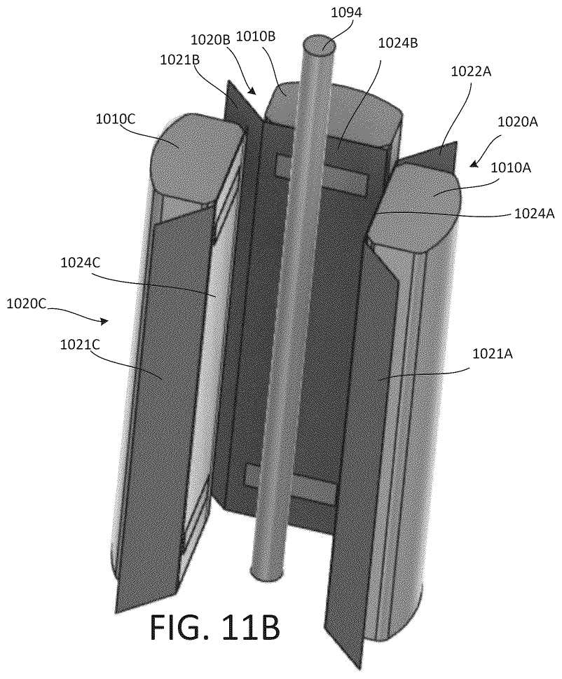

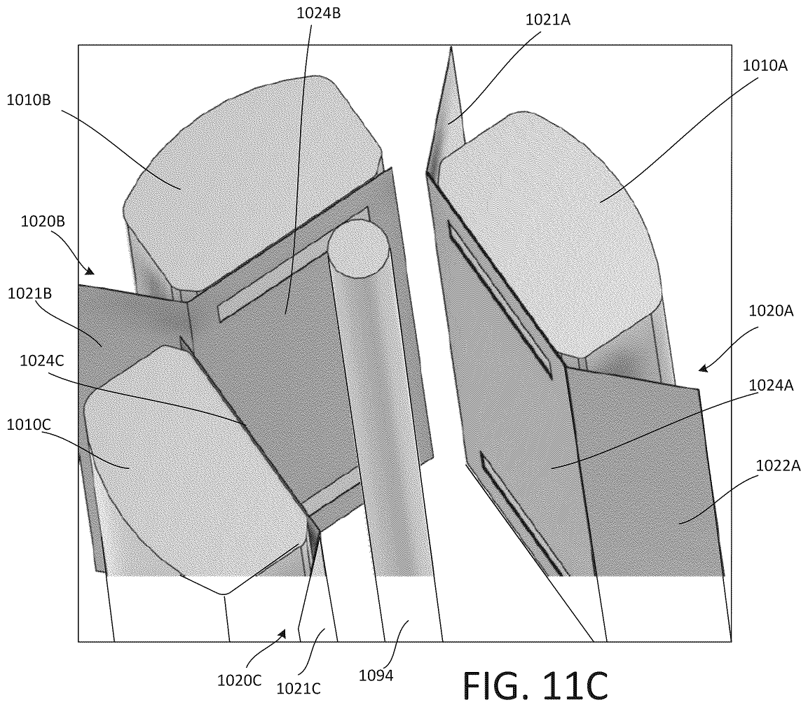

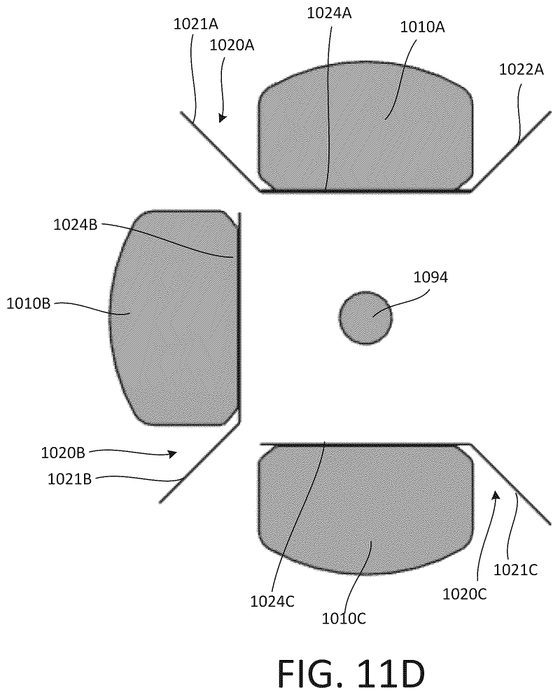

FIGS. 10A-11D illustrate an example component mounting assembly including a shielding device 1000, in accordance with implementations described herein. The example shielding device 1000, or a blocking device, can be positioned in the example component mounting assembly relative to a component such as, for example, one or more antennas, to block, or shield the component from the effects of PIM. In some examples, the example shielding device 1000 is made of a carbon fiber material that provides for the shielding, or blocking, of the component from the effects of PIM. In some examples, a contour of the example shielding device 1000 corresponds to a contour of the component. In particular, FIG. 10A is a first isometric view, and FIG. 10B is a second isometric view, of the example component mounting assembly including the example shielding device 1000. FIG. 10C is a first side view, and FIG. 10D is a second side view, of the example component mounting assembly including the example shielding device 1000. FIG. 10E is a top view, and FIG. 10F is a bottom view, of the example component mounting assembly including the example shielding device 1000. FIGS. 11A-11C are isometric views of the example component mounting assembly, with end plates removed, so that an arrangement of the example shielding device 1000 relative to the components to be shielded is more easily visible. FIG. 11D is a top schematic view of the arrangement of the example shielding device 1000 relative to the components to be shielded.

The example component mounting assembly including the shielding device 1000 includes a first end plate 1091 and a second end plate 1092 mounted on a rod 1094. The first end plate 1091, the second end plate 1092, and the rod 1094 define a receiving space in which at least one component 1010 can be received and mounted. In the example arrangement shown in FIGS. 10A-11D, a plurality of components 1010 are positioned between the first end plate 1091 and the second end plate 1092, surrounding the rod 1094. In some examples, the plurality of components 1010 includes a plurality of antennas, to be shielded from the effects of PIM by the shielding device 1000. In this example arrangement, the plurality of components includes a first component 1010A, a second component 1010B, and a third component 1010C, simply for purposes of discussion and illustration. The principles to be described herein are applicable to arrangements including more, or fewer, components, arranged similarly to or differently from the example illustrated herein.

In some examples, the shielding device 1000 includes a plurality of shielding members 1020 providing shielding for the plurality of components 1010. In the example arrangement shown in FIGS. 10A-11D, the shielding device 1000 includes a first shielding member 1020A, a second shielding member 1020B, and a third shielding member 1020C. In this example arrangement, the first shielding member 1020A is positioned proximate the first component 1010A, to provide for shielding of the first component 1010A. Similarly, the second shielding member 1020B is positioned proximate the second component 1010B and the third shielding member 1020C is positioned proximate the third component 1010C.

The first shielding member 1020A includes a panel portion 1024A, with a first arm portion 1021A and a second arm portion 1022A extending outward from opposite lateral sides of the panel portion 1024A. The second shielding member 1020B includes a panel portion 1024B, with an arm portion 1021B extending outward from a corresponding lateral side of the panel portion 1024B. The third shielding member 1020C includes a panel portion 1024C, with an arm portion 1021C extending outward from a corresponding lateral side of the panel portion 1024C. In the example arrangement shown in FIGS. 10A-11D, each lateral side of each of the components 1010 is shielded by an arm portion of one of the shielding members 1020. For example, in this example arrangement, the first component 1010A is shielded on a first lateral side by the first arm portion 1021A of the first shielding member 1020A, and is shielded on a second lateral side by the second arm portion 1022A of the first shielding member 1020A. The second component 1010B is shielded on a first lateral side by the first arm portion 1021A of the first shielding member 1020A, and on a second lateral side by the arm portion 1021B of the second shielding member 1020B. The third component 1010C is shielded on a first lateral side by the arm portion 1021B of the second shielding member 1020B, and on a second lateral side by the arm portion 1021C of the third shielding member 1020C.

In some examples, the panel portions 1024A, 1024B, 1024C of the shielding members 1020 are coupled to the respective components 1010, for example, by an adhesive or other coupling mechanism. In some examples, the shielding members 1020 are coupled, for example, fixedly coupled between the first end plate 1091 and the second end plate 1092, surrounding the rod 1094, to provide for mounting of the plurality of components 1010, for example, antennas, in the component mounting assembly. In some examples, the second end plate 1092 includes a plurality of openings 1096, at positions corresponding to the plurality of components 1010. The plurality of openings 1096 may provide for the routing of cables, wires and the like between the plurality of components 1010 mounted in the component mounting assembly and external devices.

The shielding device 1000 including the shielding members 1020 (in this example, the first shielding member 1020A, the second shielding member 1020B, and the third shielding member 1020C) is made of a composite material, such as a carbon fiber material, to shield the plurality of components 1010 from the effects of PIM. The arm portions 1021A, 1022A, 1021B, 1021C extending between adjacent components 1010 provides for shielding of the adjacent components, allowing the plurality of components 1010 to be positioned relatively closely together, and to transmit and receive signals without noise or interference due to PIM. In some examples, the shielding device 1000 including the shielding members 1020 made of the carbon fiber material shields the plurality of components 1010 from the effects of PIM, regardless of the composition of the remaining elements of the component mounting assembly (for example, the first end plate 1091 and/or the second end plate 1092 and/or the rod 1094). In some examples, the shielding device 1000 including the shielding members 1020 made of the carbon fiber material shields the plurality of components 1010 from the effects of PIM, even when the PIM is generated by one or more of the remaining elements of the component mounting assembly and/or a support structure to which the component mounting assembly is mounted.

The shielding of the components 1010, including antennas, provided by the example carbon fiber shielding members 1020 described above allows the antennas to clearly and consistently transmit and receive radio frequency (RF) signals, thus maintaining or improving the efficient and effective operation of the antennas mounted on a telecommunications tower, or other mounting structure. In some cases, example shielding members can extend the range of telecommunication signals. The shielding of the antennas provided by the example carbon fiber shielding members 1020 described above allows the components 1010, for example, antennas to clearly and consistently transmit and receive radio frequency (RF) signals even in an environment in which disturbances may be generated due to PIM in surrounding structure(s). The shielding of the components 1010, such as antennas, provided by the example carbon fiber shielding members 1020 described above may allow for components such as antennas to be more densely arranged, either on new or existing support structures, while still clearly and consistently transmitting and receiving RF signals.

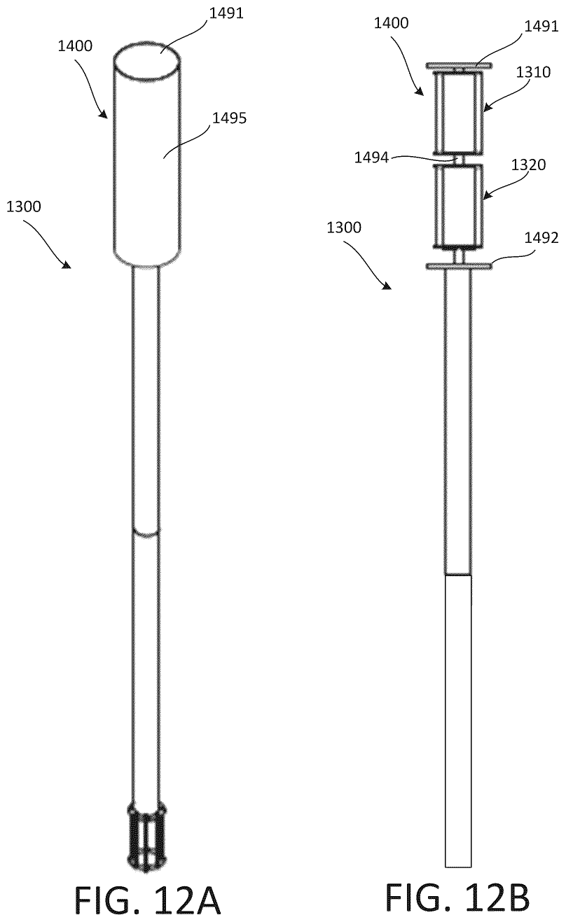

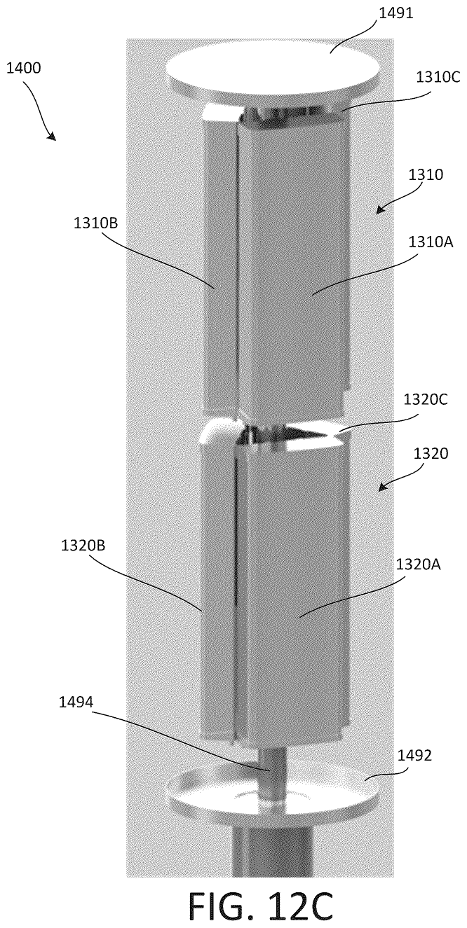

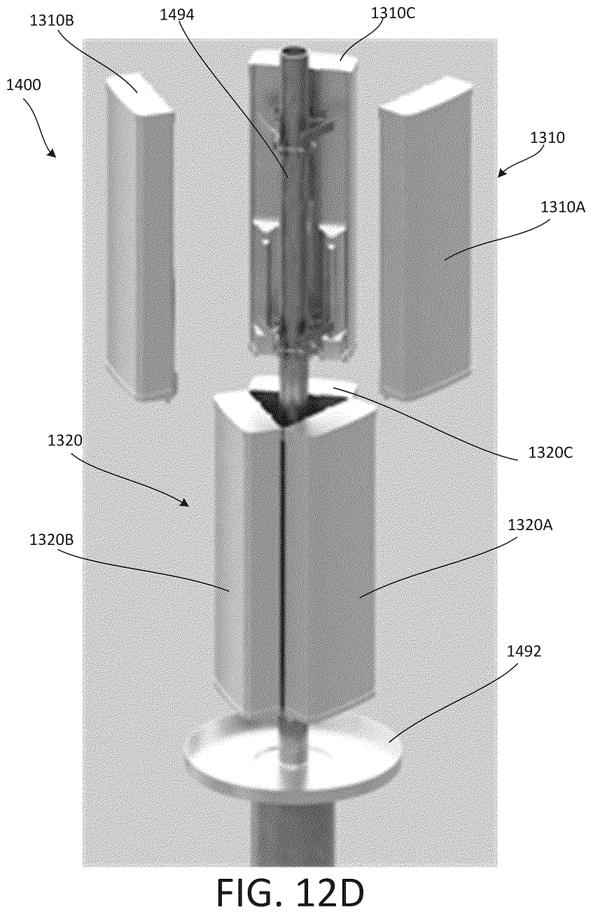

FIGS. 12A-14B illustrate an example component mounting and shielding assembly 1400, in accordance with implementations described herein. The example component mounting and shielding assembly 1400 can provide for the mounting of components, such as, for example, antennas, to reduce or substantially eliminate sources of PIM and/or to shield components, such as, for example, antennas, mounted thereon, from the effects of PIM. In some examples, at least some of the elements of the example component mounting and shielding assembly 1400 are made of a carbon fiber material, such that the carbon fiber elements do not serve as a source of PIM. In some examples, at least some of the elements of the example component mounting and shielding assembly 1400 are made of a carbon fiber material, so as to shield, or block, components mounted thereon, from the effects of PIM.

FIGS. 12A and 12B illustrate an example slim line telecommunications pole 1300 which may incorporate the example component mounting and shielding assembly 1400. FIG. 12B illustrates the example slim line telecommunications pole 1300, with a shroud 1495 removed. The example slim line telecommunications pole is shown in FIGS. 12A and 12B simply for purposes of discussion and illustration. The example component mounting and shielding assembly 1400 can be installed on other types of support structures such as, for example, the support structures described above including, for example, a frame portion coupled to a telecommunications tower, a lattice structure of a telecommunications tower, slim line telecommunications pole 800, and other such arrangements of support structures. FIG. 12C is a closer in view of the example mounting and shielding assembly 1400 with the shroud 1495 removed, illustrating a plurality of components mounted on the example mounting and shielding assembly 1400. FIG. 12D is a partially exploded view of the example arrangement shown in FIG. 12C.

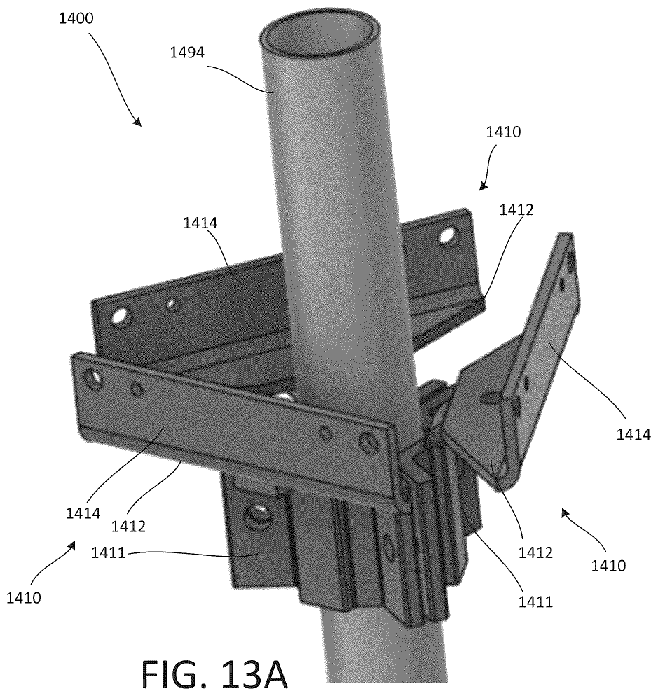

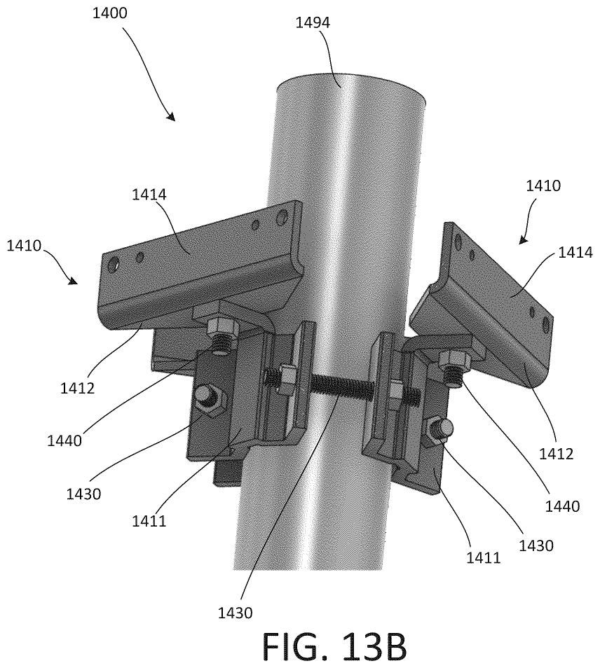

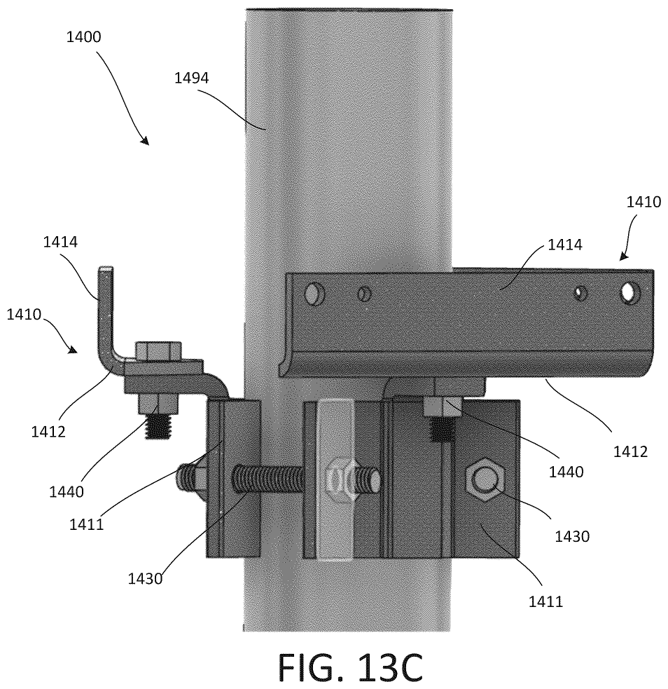

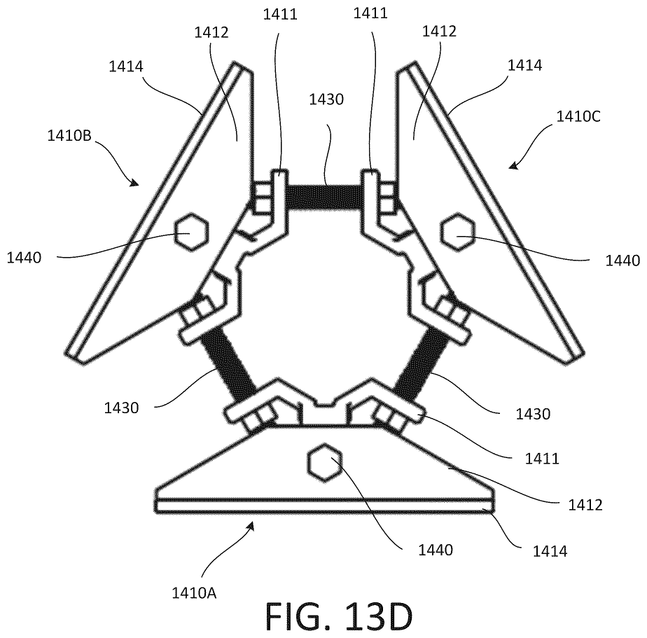

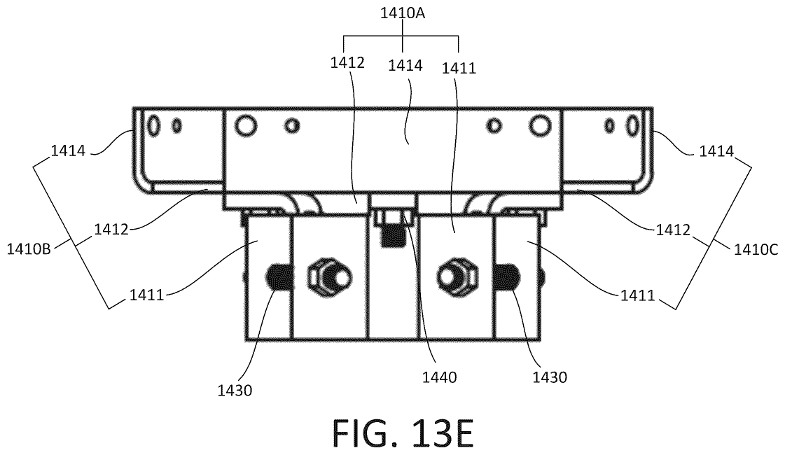

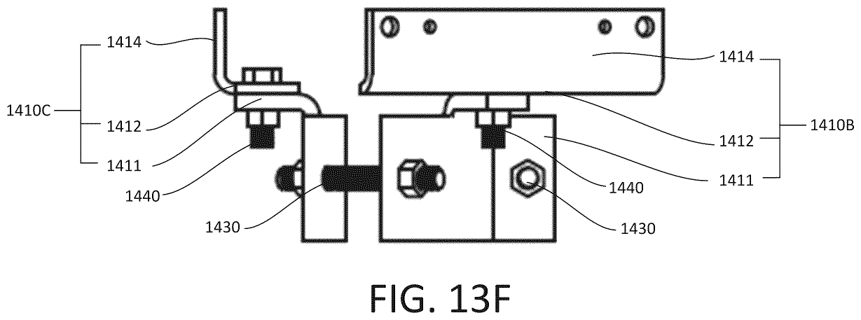

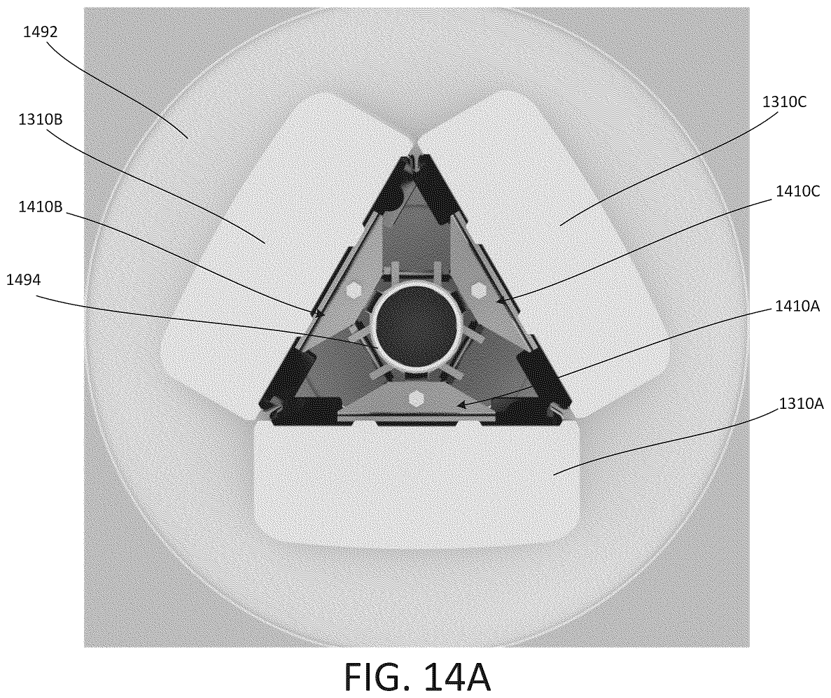

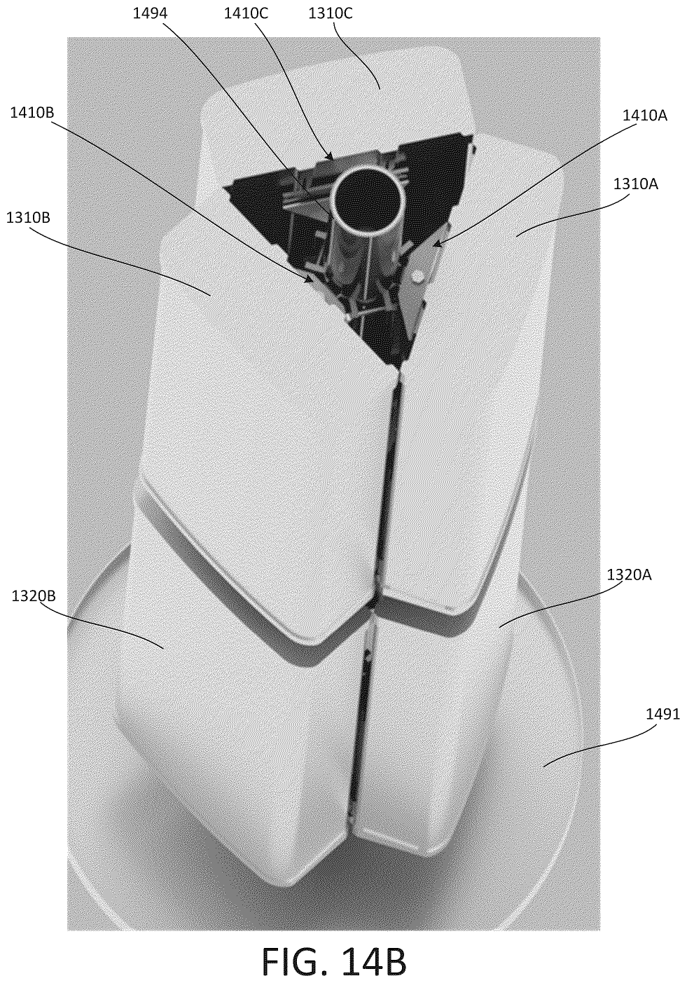

FIG. 13A is a first isometric view, FIG. 13B is a second isometric view, and FIG. 13C is a side view, of a mounting portion the example mounting and shielding assembly 1400, providing for mounting of the example components 1310, 1320 to the rod 1494. FIG. 13D is top view, FIG. 13E is a first side view, and FIG. 13F is a second side view, of the mounting portion of the example mounting and shielding assembly 1400, removed from the rod 1494. FIG. 14A is a top plan view, and FIG. 14B is an isometric top view, of the example mounting and shielding assembly 1400, with an end plate of the example mounting and shielding assembly 1400 removed, so that an internal arrangement of the mounting and shielding assembly 1400 is visible.

The example component mounting and shielding assembly 1400 includes a first end plate 1491 and a second end plate 1492 mounted on a rod 1494. The first end plate 1491, the second end plate 1492, and the rod 1494 define a receiving space in which at least one component can be received and mounted. In the example arrangement shown in FIGS. 12C and 12D, the plurality of components includes a first plurality of components 1310 surrounding the rod 1494, and a second plurality of components 1320 surrounding the rod 1494, below the first plurality of components 1310, between the first end plate 1491 and the second end plate 1492, simply for purposes of discussion and illustration. The principles to be described herein are applicable to other numbers and/or arrangements of components, on other types of support structures. In some examples, the first plurality of components 1310 and/or the second plurality of components includes a plurality of antennas. In this example arrangement, the first plurality of components 1310 includes a first component 1310A, a second component 1310B, and a third component 1310C, and the second plurality of components 1320 includes a first component 1320A, a second component 1320B, and a third component 1320C simply for purposes of discussion and illustration. The principles to be described herein are applicable to arrangements including more, or fewer, components, arranged similarly to or differently from the example illustrated herein.

As shown in FIGS. 13A-13F, in some examples, a mounting portion of the example mounting and shielding assembly 1400 includes a plurality of brackets 1410. In some examples, each of the plurality of components 1310, 1320 is mounted to the rod 1494 by a corresponding bracket 1410. In some examples, each bracket 1410 is coupled to an adjacent bracket 1410 by at least one fastener 1430 (which can include any type of coupling mechanism such as a press-fit pin, a screw, a rivet, a clamp, a dowel, and/or so forth). Coupling of the adjacent brackets 1410 and tightening of the fasteners 1430 secures a position of the brackets 1410 relative to each other on an outer surface of the rod 1494. In some examples, the at least one fastener 1430 is made of a non-conductive material, or a material that does not generate PIM (including, for example, a carbon fiber composite material as discussed above), to further mitigate potential sources of PIM.

In the example shown in FIGS. 13A-13F, each bracket 1410 includes a first portion 1411 that provides for the mounting of the bracket 1410 on the surface of the rod 1494. In the example, a second portion 1412 of the bracket 1410 extends upward and outward from the first portion 1411 of the bracket 1410. The second portion 1412 of the bracket 1410 includes a coupling surface 1414 that provides for the mounting of a component, such as, for example, one of the plurality of components 1310, 1320 described above, to the bracket 1410. In some examples, the first portion 1411 and the second portion 1412 of the bracket 1410 are formed as a single, unitary element. In some examples, the first portion 1411 and the second portion 1412 of the bracket 1410 are formed as separate elements that are coupled, for example, by at least one fastener 1440. In some examples, the at least one fastener 1440 is made of a non-conductive material, to further mitigate potential sources of PIM.

In this example, the mounting and shielding assembly 1400 includes three example brackets 1410 for each plurality of components 1310, 1320. In particular, in this example, the mounting and shielding assembly 1400 includes a first bracket 1410A for mounting of the first component 1310A (or the first component 1320A), a second bracket 1410B for mounting of the second component 1310B (or the second component 1320B), and a third bracket 1410C for mounting of the third component 1310C (or the third component 1320C). The principles described herein are applicable to other quantities and/or arrangements or brackets 1410.

In some examples, some, or all of the elements of the mounting and shielding assembly 1400 are made of a composite material. Fabricating the mounting and shielding assembly 1400 from composite materials, with no metal to metal connections, produces a system that inherently provides for PIM mitigation. Removing metal to metal connections using composite elements may reduce or substantially eliminate the sources of PIM that may affect performance of the components coupled to the mounting and shielding assembly 1400. For example, the brackets 1410 and/or the fasteners 1430 and/or the fasteners 1440 may be made of a composite material, to reduce or substantially eliminate generation of PIM due to interaction between and/or degradation of those elements of the mounting and shielding assembly 1400. In some examples, the rod 1494 is made of a composite material, to further reduce or substantially eliminate generation of PIM due to interaction of the brackets 1410 with the rod 1494.

In some examples, the arrangement of the brackets 1410, and coupling of the plurality of components 1310 and/or the plurality of components 1320 to the arrangement of brackets 1410, may provide for shielding of the components from the effects of PIM.

In some examples, the plurality of components 1310 and/or the plurality of components 1320 may be coupled to the brackets 1410 by, for example, an adhesive, fasteners, or other coupling mechanisms. In some examples, the coupling mechanism providing for coupling of the plurality of components 1310 and/or the plurality of components 1320 to the brackets 1410 is a non-conductive coupling mechanism, or a coupling mechanism made of a material that does not generate PIM (including, for example, a carbon fiber composite material as discussed above), to further mitigate potential sources of PIM. In some examples, the plurality of components 1310 and/or the plurality of components 1320 are mounted on the brackets 1410 surrounding the rod 1494, and received in a receiving space defined by the first end plate 1491, the second end plate 1492 and the shroud 1495. In some examples, the first end plate 1491 and/or the second end plate 1492 and/or the shroud 1495 are also made of a composite material, providing shielding of the plurality of components 1310 and/or the plurality of components 1320 from PIM due to external sources of PIM. The relative positioning of the plurality of components 1310 and/or the plurality of components 1320 as shown may provide for shielding of the plurality of components 1310 and/or the plurality of components 1320 from the effects of PIM while still being positioned relatively closely together. This may allow the components 1310, 1320 to transmit and receive signals without noise or interference due to PIM.

The shielding of the components 1310, 1320, including antennas, provided by the example mounting and shielding assembly 1400 described above allows the antennas to clearly and consistently transmit and receive radio frequency (RF) signals, thus maintaining the efficient and effective operation of the antennas mounted on a telecommunications tower, a slim line telecommunications pole, or other mounting structure. This shielding of the antennas allows the components 1310, 1320, for example, antennas to clearly and consistently transmit and receive radio frequency (RF) signals even in an environment in which disturbances may be generated due to PIM in surrounding structure(s). Shielding can also allow signals to be transmitted effectively over longer distances. This shielding of the components 1310, 1320, such as antennas, may allow for components such as antennas to be more densely arranged, either on new or existing support structures, while still clearly and consistently transmitting and receiving RF signals.

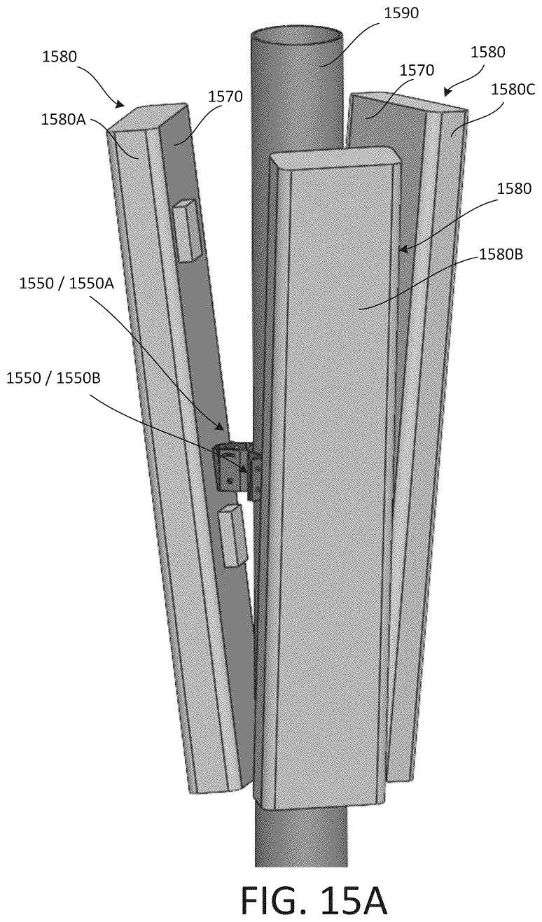

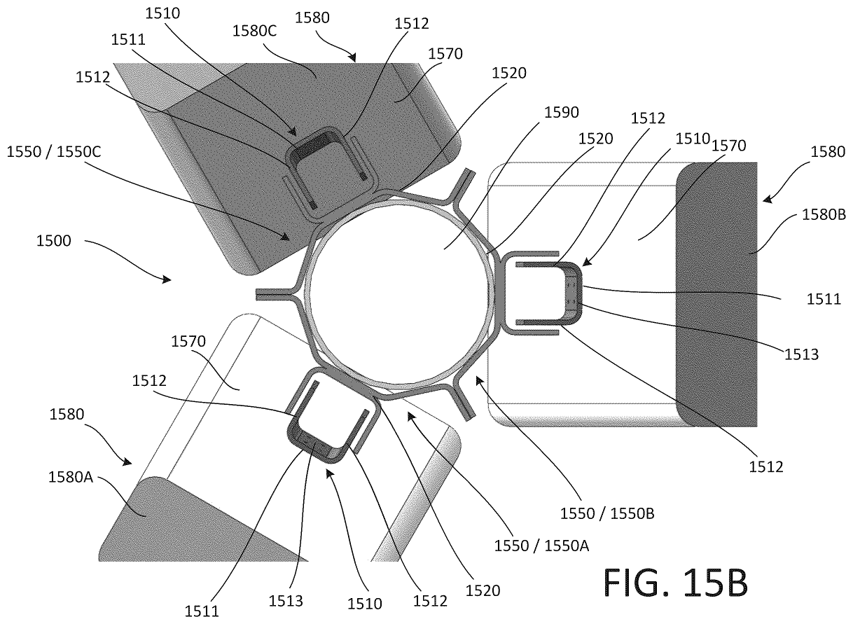

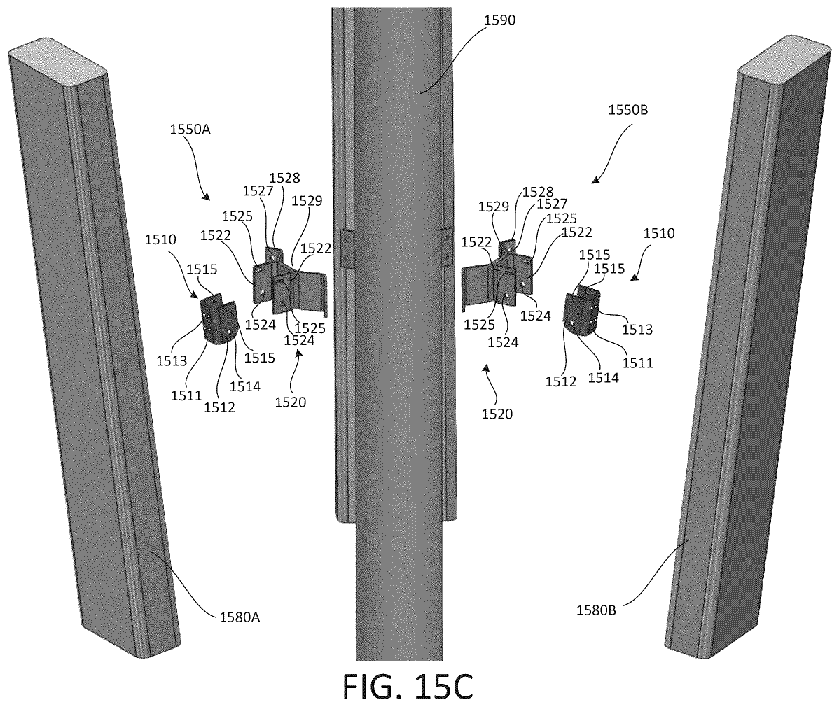

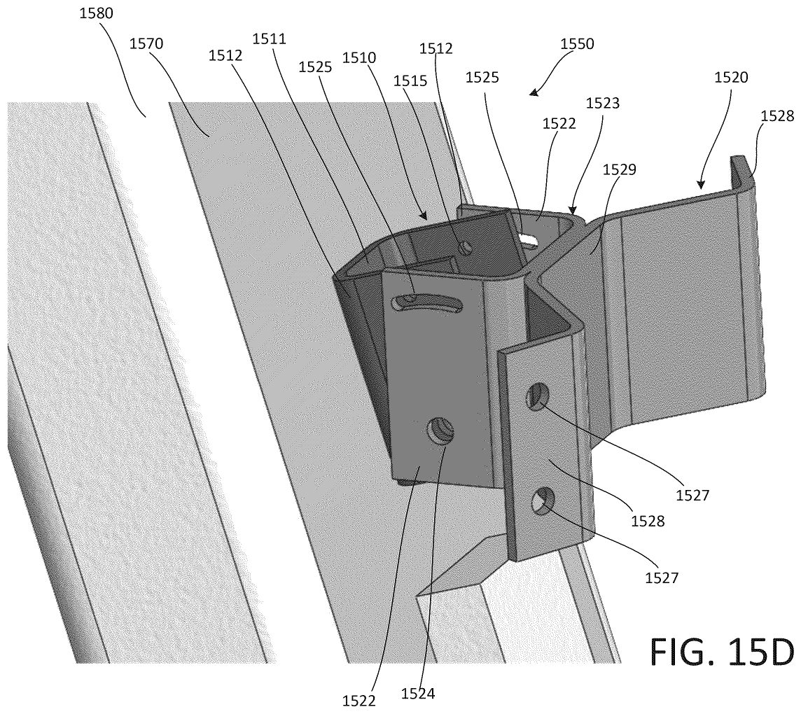

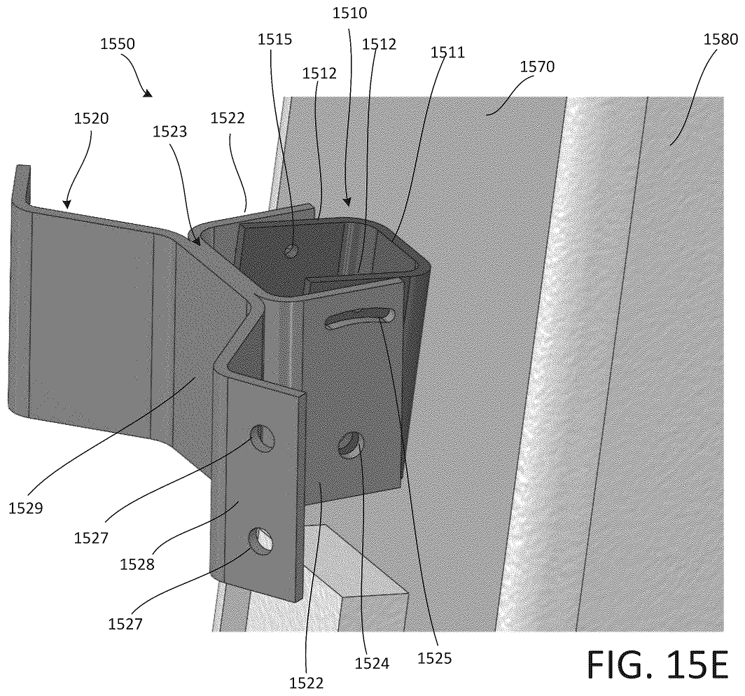

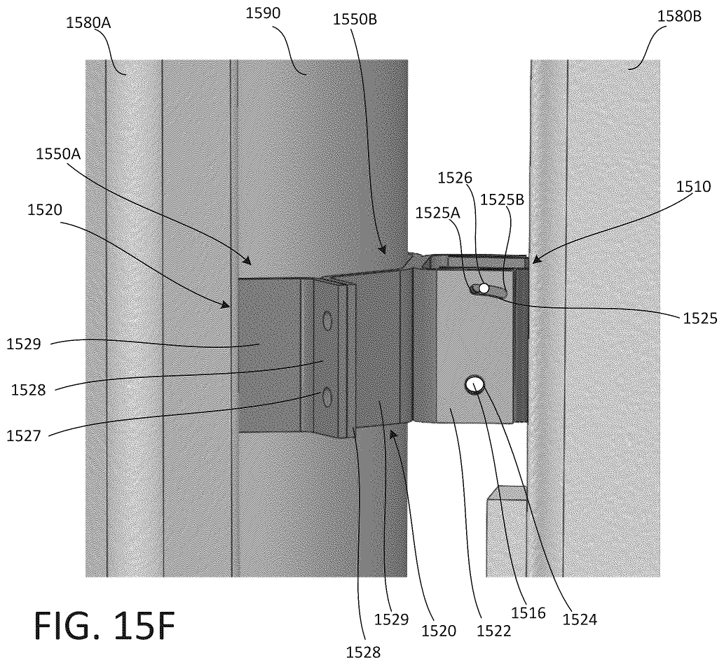

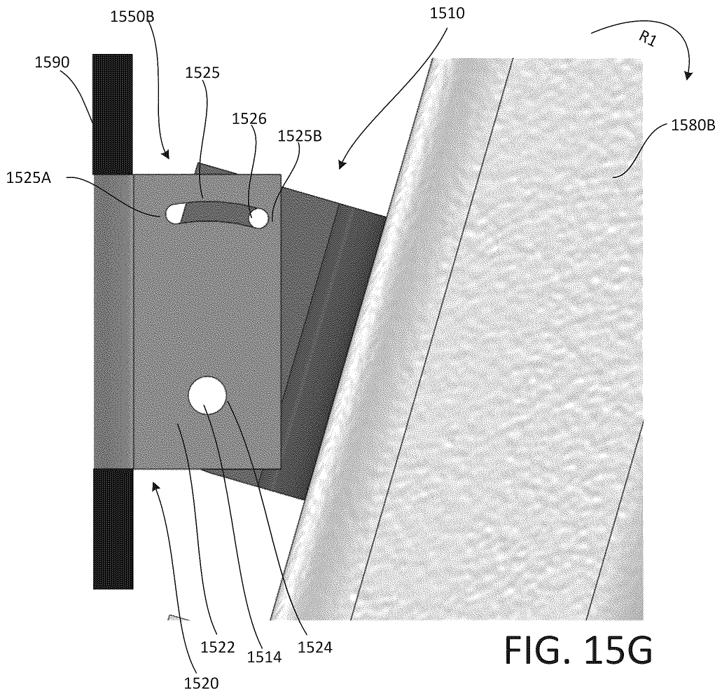

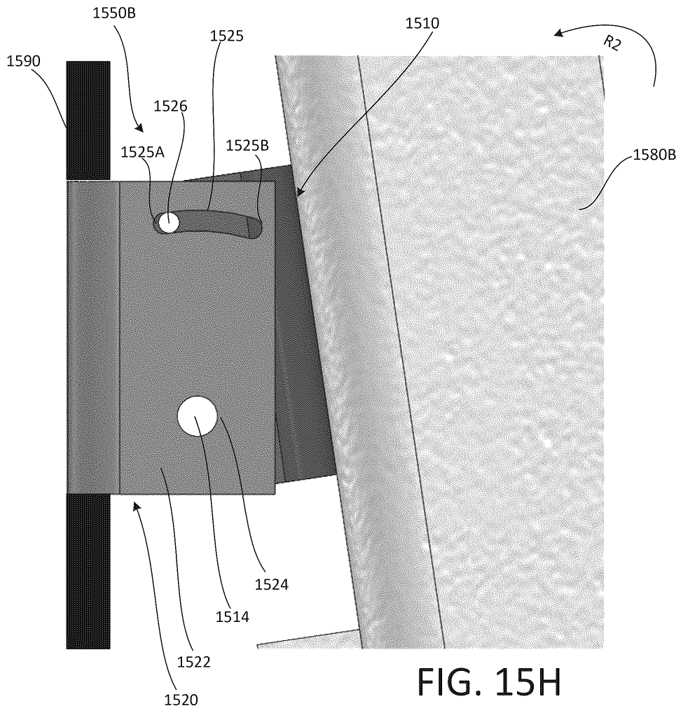

FIGS. 15A-15H illustrate an example component mounting assembly 1500 providing for the mounting of a plurality of components 1580 on a support structure 1590, such as, for example, a pole. FIG. 15B is a top view of the example mounting assembly 1500 providing for the mounting of the plurality of components 1580 on the support structure 1590. FIG. 15C is an exploded view of the example mounting assembly 1500 providing for the mounting of the plurality of components 1580 on the support structure 1590. FIG. 15D is a first perspective view, and FIG. 15E is a second perspective view, of the example mounting assembly 1500 relative to one of the plurality of components 1580, with the support structure 1590 removed. FIG. 15F is a close-in view of the mounting of one of the plurality of components 1580 on the support structure 1590, in a first orientation. FIG. 15G is a close-in view of the mounting of one of the plurality of components 1580 on the support structure 1590, in a second orientation. FIG. 15H is a close-in view of the mounting of one of the plurality of components 1580 on the support structure 1590, in a third orientation.

The example support structure 1590 in the form of a pole, for example for use in a slim line telecommunications assembly, is shown in FIGS. 15A-15H, simply for purposes of discussion and illustration. The example component mounting assembly 1500 can be installed on other types of support structures such as, for example, the support structures described above including, for example, a frame portion coupled to a telecommunications tower, a lattice structure of a telecommunications tower, and other such arrangements of support structures.

In the example arrangement shown in FIGS. 15A-15H, the example component mounting assembly 1500 provides for the mounting of three components, for example, a first component 1580A, a second component 1580B, and a third component 1580C, simply for purposes of discussion and illustration. In the example arrangement shown in FIGS. 15A-15H, the example component mounting assembly 1500 includes a plurality of bracket assemblies 1550 (for example, a first bracket assembly 1550A, a second bracket assembly 1550B, and a third bracket assembly 1550C), respectively providing for the mounting of the plurality of components 1580, simply for purposes of discussion and illustration. The principles described herein are applicable to component mounting assemblies providing for the mounting of more, or fewer components on a structural support member.

In the example arrangement shown in FIGS. 15A-15H, each example bracket assembly 1550 includes a first bracket 1510 that is coupled to the respective component 1580, and a second bracket 1520 that is coupled between the first bracket 1510 and the support structure 1590, to couple the component 1580 to the support structure 1590. In the example arrangement shown in FIGS. 15A-15H, the first bracket 1510 is a U-shaped, or C-shaped bracket, including a base wall 1511 and opposing side walls 1512. One or more openings 1513 are formed in the base wall 1511, to respectively receive one or more fasteners (not explicitly shown in FIGS. 15A-15H) for fastening the first bracket 1510 to the component 1580. In some examples, the one or more fasteners fastening the first bracket 1510 to the component 1580 are made of a non-conductive material, or of a material that does not generate PIM (including, for example, a carbon fiber composite material as discussed above), to further mitigate potential sources of PIM.

In the example arrangement shown in FIGS. 15A-15H, the second bracket 1520 includes a base wall 1529 configured to mate with a supporting surface of the support structure 1590. In some examples, a contour of the base wall 1529 of the second bracket 1520 corresponds to, or is designed to mate with, a contour of the support surface of the support structure 1590, to provide for stable support of the second bracket 1520 on the support structure 1590. Flange portions 1528 extend outward from the base wall 1529, with at least one opening 1527 formed therein to receive a fastener (not explicitly shown in FIGS. 15A-15H) for coupling of the flange portion 1528 of the second bracket 1520 to the flange portion 1528 of an adjacent second bracket 1520, such that plurality of second brackets 1520 coupled in this manner surround the support structure 1590 (in the form of a pole in this example arrangement), forming a ring that is secured on the support structure 1590. In some examples, the one or more fasteners fastening the respective flange portions 1528 of the adjacent second brackets 1520 are made of a non-conductive material, or a material that does not generate PIM (including, for example, a carbon fiber composite material as discussed above), to further mitigate potential sources of PIM. A coupling portion 1523 of the second bracket 1520, in the form of a U-shaped bracket portion, or a C-shaped bracket portion, includes side walls 1522 extending outward from the base wall 1529, in a direction away from the support structure 1590, and toward the component 1580. In the example arrangement shown in FIGS. 15A-15H, the side walls 1522 of the second bracket 1520 are positioned at outer sides of the side walls 1512 of the first bracket 1510, to provide for coupling of the first bracket 1510 and the second bracket 1520.

In particular, openings 1514 in each of the side walls 1512 of the first bracket 1510 may be positioned corresponding to openings 1524 in the side walls 1522 of the second bracket 1520. Openings 1515 in each of the side walls 1512 of the first bracket 1510 may be positioned corresponding to openings 1525, in the form of slots, formed in the side walls 1522 of the second bracket 1520. When the side walls 1522 of the second bracket 1520 are positioned adjacent to the side walls 1512 of the first bracket 1510, a first fastener 1516, such as, for example, a bolt, may extend through each opening 1524 in the second bracket 1520 and the corresponding opening 1514 in the second bracket 1520, and a second fastener 1526, such as, for example, a bolt, may extend through each opening 1525 in the second bracket 1520 and the corresponding opening 1515 in the first bracket 1510, to couple the first bracket 1510 and the second bracket 1520. In some examples, the first fastener 1516 and/or the second fastener 1526 are made of a non-conductive material, or of a material that does not generate PIM (including, for example, a carbon fiber composite material as discussed above), to further mitigate potential sources of PIM.

In some examples, a position of the component 1580 may be adjusted, for example, tilted, relative to the support structure 1590 by adjusting a position of the second fastener 1526 in the openings 1525 formed in the side walls 1522 of the second bracket 1520. FIG. 15F illustrates a first position of one of the plurality of 1580 relative to the support structure 1590. In FIG. 15F, the component 1580 is substantially aligned with, or relatively parallel to, the support structure 1590. FIG. 15G illustrates a second position of one of the plurality of 1580 relative to the support structure 1590, in which the component 1580 is rotated, or tilted, or pivoted, in the direction of the arrow R1 with respect to the support structure 1590. FIG. 15H illustrates a third position of one of the plurality of 1580 relative to the support structure 1590, in which the component 1580 is rotated, or tilted, or pivoted, in the direction of the arrow R2 with respect to the support structure 1590. In FIGS. 15F-15H, first fasteners 1516 extend through the aligned openings 1514, 1524 in the side walls 1512, 1522 of the first and second brackets 1510, 1520, to couple the respective lower end portions of the side walls 1512, 1522 of the first and second brackets 1510, 1520. Second fasteners 1526 extend through the aligned openings 1515, 1525 in the side walls 1512, 1522 of the first and second brackets 1510, 1520, to couple the respective upper end portions of the side walls 1512, 1522 of the first and second brackets 1510, 1520.

In some examples, to couple the first and second brackets 1510, 1520 of each of the plurality of bracket assemblies 1550, the first fasteners 1516 are positioned in the aligned openings 1515, 1525 to provide for initial coupling of the first and second brackets 1510, 1520. The second fasteners 1526 are then inserted through the aligned openings 1515, 1525 in the side walls 1512, 1522 of the first and second brackets 1510, 1520. As the openings 1525 in the side walls 1522 of the second bracket 1520 are formed as a slot, for example, an arcuate slot, the second fastener 1526 may be slidably received in the opening 1525 having the form of an arcuate slot, allowing the component 1580 to be rotated in the direction of the arrow R1 and/or the direction of the arrow R2, to adjust a position of the component 1580 relative to the support structure 1590. The first fastener 1516 and the second fastener 1526 may then be tightened to set a selected position of the component 1580 relative to the support structure 1590.

In the position shown in FIG. 15F, in which the component 1580 is substantially aligned with, or oriented relatively in parallel to the support structure 1590, the second fastener 1526 is positioned at an intermediate position in the opening 1525, between a first end portion 1525A and a second end portion 1525B of the opening 1525 in the side wall 1522 of the second bracket 1520 having the form of an arcuate slot. In the position shown in FIG. 15G, the second fastener 1526 is positioned at the second end portion 1525B of the opening 1525 in the side wall 1522 of the second bracket 1520 having the form of an arcuate slot, at a maximum rotated position of the component 1580 in the direction of the arrow R1. In the position shown in FIG. 15H, the second fastener 1526 is positioned at the first end portion 1525B of the opening 1525 in the side wall 1522 of the second bracket 1520 having the form of an arcuate slot, at a maximum rotated position of the component 1580 in the direction of the arrow R2. The example positions of the component 1580 relative to the support structure 1590 are provided simply for purposes of discussion and illustration. Rotation of the component 1580 may be guided by the sliding movement of the second fastener 1526 between the first and second end portions 1525A, 1525B of the opening 1525, to a plurality of different positions of the component 1580 relative to the support structure 1590.

In some examples, the component mounting assembly 1500 includes a shielding member 1570. In the example arrangement shown in FIGS. 15A-15H, the shielding member 1570 is positioned between the support structure 1590 and a corresponding surface of the component 1580. In some examples, the shielding member 1570 is adhered to the surface of the component 1580. In some examples, the component 1580 and the shielding member 1570 are coupled to each other in other ways. In some examples, the shielding member 1570 is positioned proximate the surface of the component 1580, but not affixed directly to the component 1580. In some examples, the shielding member 1570 is made of a composite material, for example, a carbon fiber material, to shield the component 1580 from the effects of PIM. In this example arrangement, the shielding member 1570 is a substantially planar panel, having a shape, or contour, corresponding to a mating or coupling surface of the component 1580, simply for purposes of discussion and illustration. The principles described herein are applicable to shielding members having different configurations.

In some examples, some, or all of the elements of the mounting assembly 1500 are made of a composite material. Fabricating the mounting assembly 1500 from composite materials avoids metal to metal connections, and produces a system that inherently provides for PIM mitigation. Removing metal to metal connections using composite elements may reduce or substantially eliminate the sources of PIM that may affect performance of the components 1580 coupled to the mounting assembly 1500. For example, the first bracket 1510 and/or the second bracket 1520 and/or the first fastener 1516 and/or the second fastener 1526 may be made of a composite material, to reduce or substantially eliminate generation of PIM due to interaction between and/or degradation of those elements of the mounting assembly 1500. In some examples, the first fastener 1516 and/or the second fastener may be made of a non-conductive material, or a material that does not generate PIM (including, for example, a carbon fiber composite material as discussed above), to further mitigate potential sources of PIM. In some examples, the support structure 1590 is made of a composite material, to further reduce or substantially eliminate generation of PIM due to interaction of the bracket assemblies 1550 with the support structure 1590. In some examples, the arrangement of the bracket assemblies 1550, and coupling of the plurality of components 1580 to the plurality of bracket assemblies 1550, may provide for shielding of the components 1580 from the effects of PIM. In some examples, the relative positioning of the plurality of components 1580 by the plurality of bracket assemblies 1550 may provide for shielding of the plurality of components 1580 from the effects of PIM while still allowing the plurality of components 1580 to be positioned relatively closely together. This may allow the plurality of components 1580 to transmit and receive signals without noise or interference due to PIM.

Reducing or substantially eliminating sources of PIM, and shielding of the plurality of components 1580, including for example, antennas, provided by the example mounting assembly 1500 described above allows the antennas to clearly and consistently transmit and receive radio frequency (RF) signals, thus maintaining the efficient and effective operation of the antennas mounted on a telecommunications tower, a slim line telecommunications pole, or other mounting structure. This allows the plurality of components 1580, for example, antennas, to clearly and consistently transmit and receive radio frequency (RF) signals by reducing disturbances generated due to PIM in surrounding structure(s). This may also allow signals to be transmitted effectively over longer distances. This may allow for components such as antennas to be more densely arranged, either on new or existing support structures, while still clearly and consistently transmitting and receiving RF signals. The mounting assembly 1500 also allows components to have a fine-tuned angle of signal, providing for functionality with various antennas and site locations.

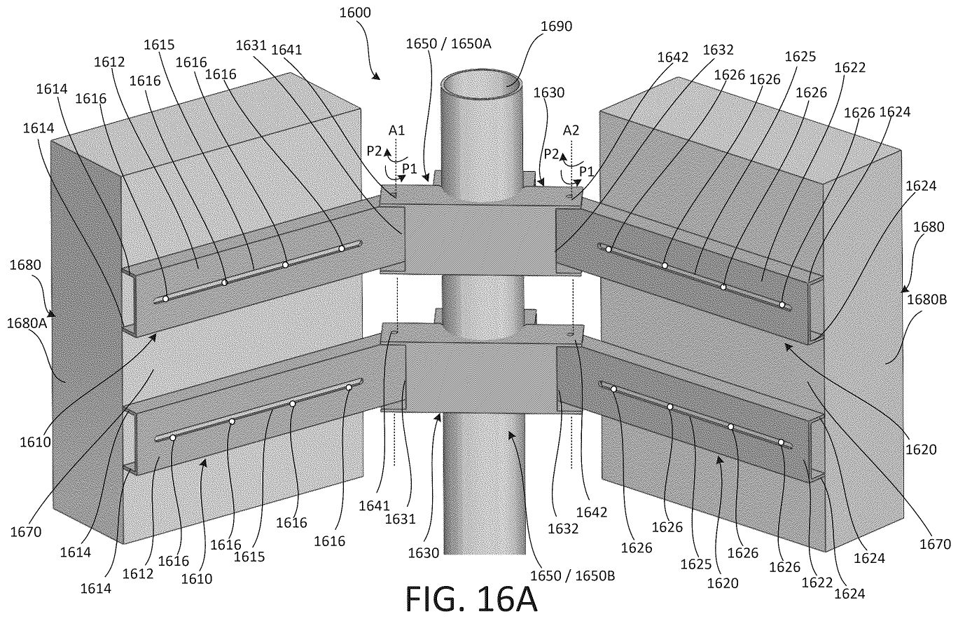

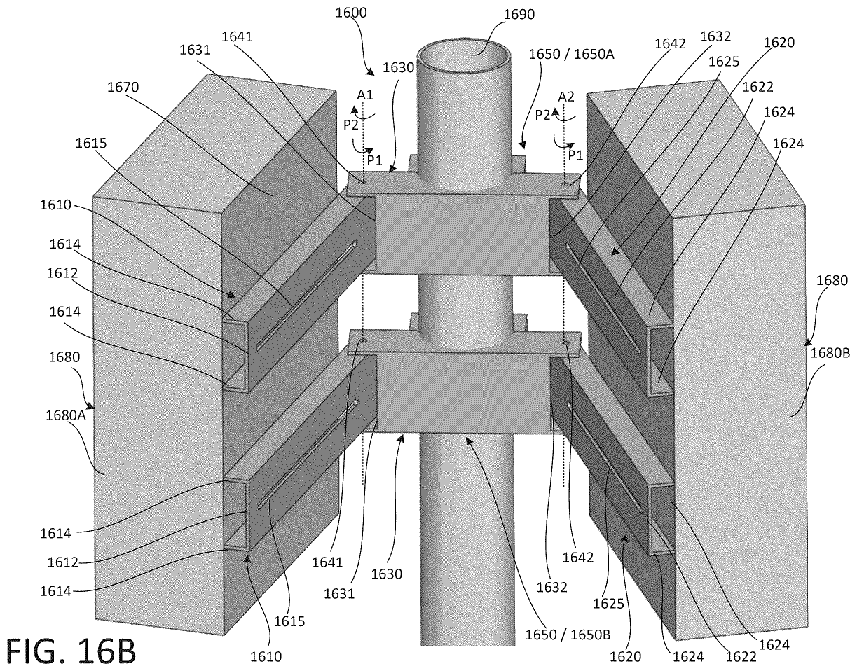

FIGS. 16A and 16B illustrate an example component mounting assembly 1600 providing for the mounting of a plurality of components 1680 on a support structure 1690, such as, for example, a pole. FIG. 16A illustrates a first orientation, or arrangement, of the plurality of components 1680 relative to the support structure 1690. FIG. 16B illustrates a second orientation, or arrangement, of the plurality of components 1680 relative to the support structure 1690. FIGS. 16A and 16B provide two example orientations, or arrangements, of the plurality of components relative to the support structure 1690, in the form of a pole, provided for by the example component mounting assembly 1600, simply for purposes of discussion and illustration. The principles described herein provide for other arrangements of more, or fewer, components by the example component mounting assembly 1600 than explicitly described herein.

The example the support structure 1690 in the form of a pole (for example, for use in a slim line telecommunications assembly) is shown in FIGS. 16A and 16B, simply for purposes of discussion and illustration. The example component mounting assembly 1600 can be installed on other types of support structures such as, for example, the support structures described above including, for example, a frame portion coupled to a telecommunications tower, a lattice structure of a telecommunications tower, and other such arrangements of support structures.

In the example arrangement shown in FIGS. 16A and 16B, the example component mounting assembly 1600 provides for the mounting of two components, for example, a first component 1680A, and a second component 1680B, simply for purposes of discussion and illustration. In the example arrangement shown in FIGS. 16A and 16B, the example component mounting assembly 1600 includes a plurality of bracket assemblies 1650 (for example, a first bracket assembly 1650A, and a second bracket assembly 1650B). In this example, arrangement, the first bracket assembly 1650A and the second bracket assembly 1650B are substantially the same, each providing for coupling of both the first component 1680A and the second component 1680B to the support structure 1690, simply for purposes of discussion and illustration. The principles described herein are applicable to more, or fewer, bracket assemblies providing for the mounting of more, or fewer components on a structural support member.

In the example arrangement shown in FIGS. 16A and 16B, each example bracket assembly 1650 includes a central bracket 1630 that is coupled to the support structure 1690. An end portion of a first arm 1610 of the bracket assembly 1650 is coupled to a first end portion of the central support bracket 1630 at a first pivotable coupling 1641. The first arm 1610 is coupled to the first component 1680A, to provide for coupling, for example, pivotable or rotatable coupling about an axis A1, of the first component 1680A to the support structure 1690 by the bracket assembly 1650. An end portion of a second arm 1620 of the bracket assembly 1650 is coupled to a second end portion of the central support bracket 1630 at a second pivotable coupling 1642. The second arm 1620 is coupled to the second component 1680B, to provide for coupling, for example, pivotable or rotatable coupling about an axis A2, of the second component to the support structure 1690 by the bracket assembly 1650.

In some examples, the first arm 1610 includes a body portion 1612, and support legs 1614 extending outward, from opposite lateral sides of the body portion 1612 toward the first component 1680A. In some examples, the U-shaped, or C-shaped structure of the first arm 1610 of the bracket assembly 1650 enhances the structural support of the first arm 1610 provided to the first component 1680A. An opening 1615, in the form of a slot, is formed in the body portion 1612 of the first arm 1610. In this example arrangement, the opening 1615 extends in a longitudinal direction of the first arm 1610. One or more fasteners 1616 may be inserted through the opening 1615 and into the first component 1680A, to couple the first component 1680A to the support structure 1690 via the first arm 1610 and the central support bracket 1630 of the bracket assembly 1650. In some examples, the one or more fasteners 1616 fastening the first arm 1610 to the first component 1680A are made of a non-conductive material, or a material that does not generate PIM (including, for example, a carbon fiber composite material as discussed above), to further mitigate potential sources of PIM. The elongated nature of the opening 1615 in the form of a slot allows for insertion of fasteners 1616 at a variety of different locations along the length of the first arm 1610, to accommodate mounting or connection points provided on the first component 1680A.

In some examples, the second arm 1620 includes a body portion 1622, and support legs 1624 extending outward, from opposite lateral sides of the body portion 1622 toward the second component 1680B. In some examples, the U-shaped, or C-shaped structure of the second arm 1620 of the bracket assembly 1650 enhances the structural support of the second arm 1620 provided to the second component 1680B. An opening 1625, in the form of a slot, is formed in the body portion 1622 of the second arm 1620. In this example arrangement, the opening 1625 extends in a longitudinal direction of the second arm 1620. One or more fasteners 1626 may be inserted through the opening 1625 and into the second component 1680B, to couple the second component 1680B to the support structure 1690 via the second arm 1620 and the central support bracket 1630 of the bracket assembly 1650. In some examples, the one or more fasteners 1626 fastening the second arm 1620 to the second component 1680B are made of a non-conductive material, or a material that does not generate PIM (including, for example, a carbon fiber composite material as discussed above), to further mitigate potential sources of PIM. The elongated nature of the opening 1625 in the form of a slot allows for insertion of fasteners 1626 at a variety of different locations along the length of the second arm 1620, to accommodate mounting or connection points provided on the second component 1680B.

In the example arrangement shown in FIGS. 16A and 16B, the central support bracket 1630 includes a first cutaway portion 1631 to accommodate rotation of the first arm 1610 at the first pivotable coupling 1641 about the axis A1, and a second cutaway portion 1632 to accommodate rotation of the second arm 1620 at the second pivotable coupling 1642 about the axis A2. In some examples, the first pivotable coupling 1641 includes a fastening pin, such as, for example, a rod, a pin, a dowel, a bolt and the like, extending through an opening in an upper portion of the first end portion of the central support bracket 1630 (for example, proximate the first cutaway portion 1631), through corresponding openings formed in end portions of the legs 1614 of the first arm 1610, and through an opening in a lower portion of the first end portion of the central support bracket 1630. Similarly, the second pivotable coupling 1642 includes a fastening pin, such as, for example, a rod, a pin, a dowel, a bolt and the like, extending through an opening in an upper portion of the second end portion of the central support bracket 1630 (for example, proximate the second cutaway portion 1632), through corresponding openings formed in end portions of the legs 1624 of the second arm 1620, and through an opening in a lower portion of the second end portion of the central support bracket 1630. FIG. 16B illustrates an example rotation of the first component 1680A in the direction of the arrow PI about the axis A1, and an example rotation of the second component 1680B in the direction of the arrow P2 about the axis A2, from the example arrangement shown in FIG. 16A. In some examples, the first pivotable coupling 1641 and/or the second pivotable coupling 1642 are made of a non-conductive material (including, for example, a carbon fiber composite material as discussed above), to further mitigate potential sources of PIM.

FIGS. 16A and 16B illustrate two example positions of the first and second components 1680A, 1680B relative to the support structure 1690 and/or relative to each other, simply for purposes of discussion and illustration. The first component 1680A and/or the second component 1680B may be rotated, or pivoted, about the respective axis of rotation to a plurality of different positions.

In some examples, the component mounting assembly 1600 includes a shielding member 1670. In the example arrangement shown in FIGS. 16A and 16B, the shielding member 1670 is positioned between the support structure 1690 and a corresponding surface of the component 1680. In some examples, the shielding member 1670 is adhered to the surface of the component 1680. In some examples, the component 1680 and the shielding member 1670 are coupled to each other in other ways. In some examples, the shielding member 1670 is positioned proximate the surface of the component 1680, but not affixed directly to the component 1680. In some examples, the shielding member 1670 is made of a composite material, for example, a carbon fiber material, to shield the component 1580 from the effects of PIM. In this example arrangement, the shielding member 1670 is a substantially planar panel, having a shape, or contour, corresponding to a mating or coupling surface of the component 1680, simply for purposes of discussion and illustration. The principles described herein are applicable to shielding members having different configurations.

In some examples, some, or all of the elements of the mounting assembly 1600 are made of a composite material. Fabricating the mounting assembly 1600 from composite materials avoids metal to metal connections, and produces a system that inherently provides for PIM mitigation. Removing metal to metal connections using composite elements may reduce or substantially eliminate the sources of PIM that may affect performance of the components 1680 coupled to the mounting assembly 1600. For example, the central bracket 1630 and/or the first arm 1610 and/or the second arm 1620 and/or the fasteners 1616, 1626 may be made of a composite material, to reduce or substantially eliminate generation of PIM due to interaction between and/or degradation of those elements of the mounting assembly 1600. In some examples, the first pivotable coupling 1641 and/or the second pivotable coupling 1642 are made of a non-conductive material, or a material that does not generate PIM (including, for example, a carbon fiber composite material as discussed above), to further mitigate potential sources of PIM. In some examples, the support structure 1690 is made of a composite material, to further reduce or substantially eliminate generation of PIM due to interaction of the bracket assemblies 1650 with the support structure 1690. In some examples, the arrangement of the bracket assemblies 1650, and coupling of the plurality of components 1680 to the plurality of bracket assemblies 1650, may provide for shielding of the components 1680 from the effects of PIM. In some examples, the relative positioning of the plurality of components 1680 by the plurality of bracket assemblies 1650 may provide for shielding of the plurality of components 1680 from the effects of PIM while still allowing the plurality of components 1680 to be positioned relatively closely together. This may allow the plurality of components 1680 to transmit and receive signals without noise or interference due to PIM.

Reducing or substantially eliminating sources of PIM, and shielding of the plurality of components 1680, including for example, antennas, provided by the example mounting assembly 1600 described above allows the antennas to clearly and consistently transmit and receive radio frequency (RF) signals, thus maintaining the efficient and effective operation of the antennas mounted on a telecommunications tower, a slim line telecommunications pole, or other mounting structure. This allows the plurality of components 1580, for example, antennas to clearly and consistently transmit and receive radio frequency (RF) signals by reducing disturbances generated due to PIM in surrounding structure(s). This may also allow signals to be transmitted effectively over longer distances. This may allow for components such as antennas to be more densely arranged, either on new or existing support structures, while still clearly and consistently transmitting and receiving RF signals. The mounting assembly 1500 also allows components to have a fine-tuned angle of signal, providing for functionality with various antennas and site locations.

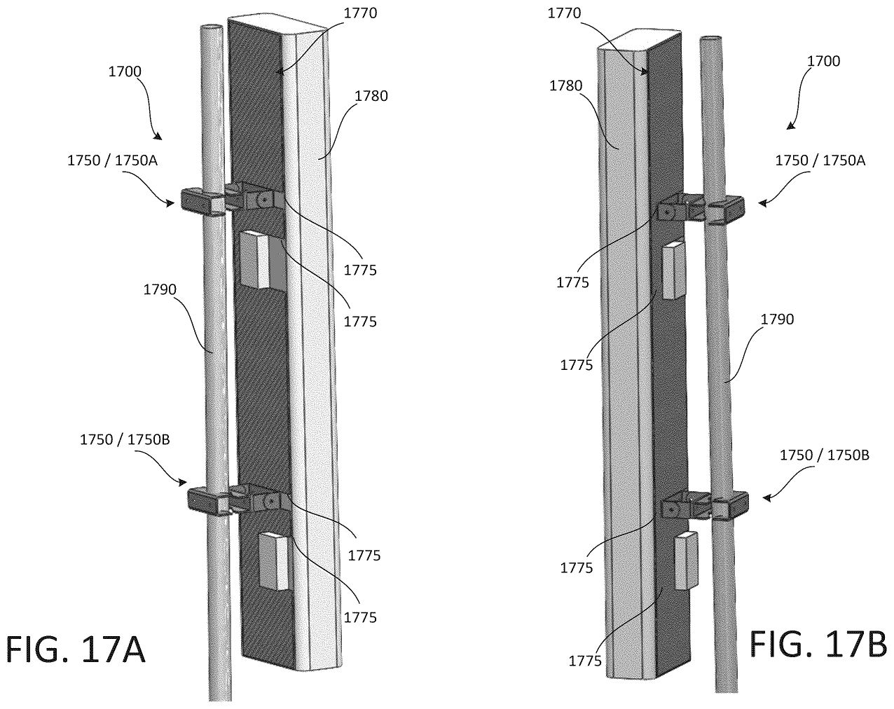

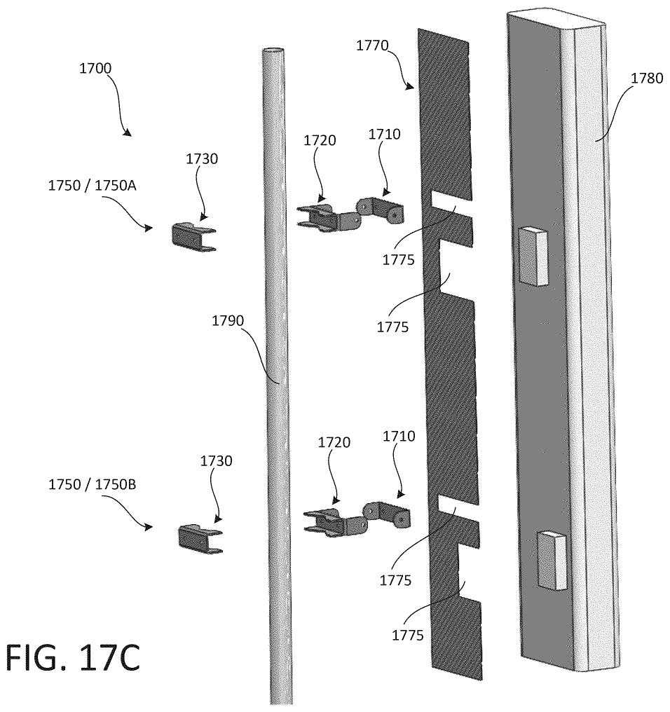

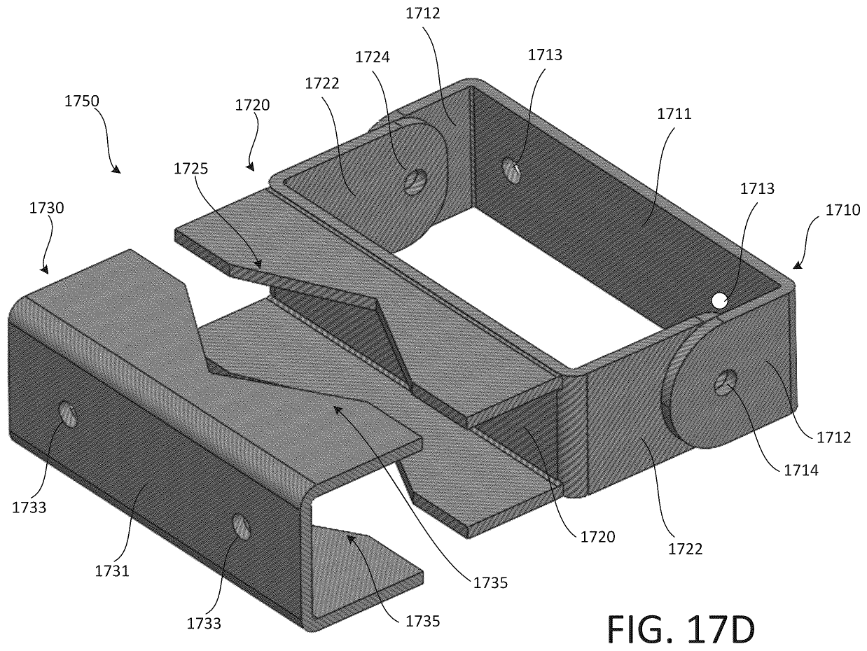

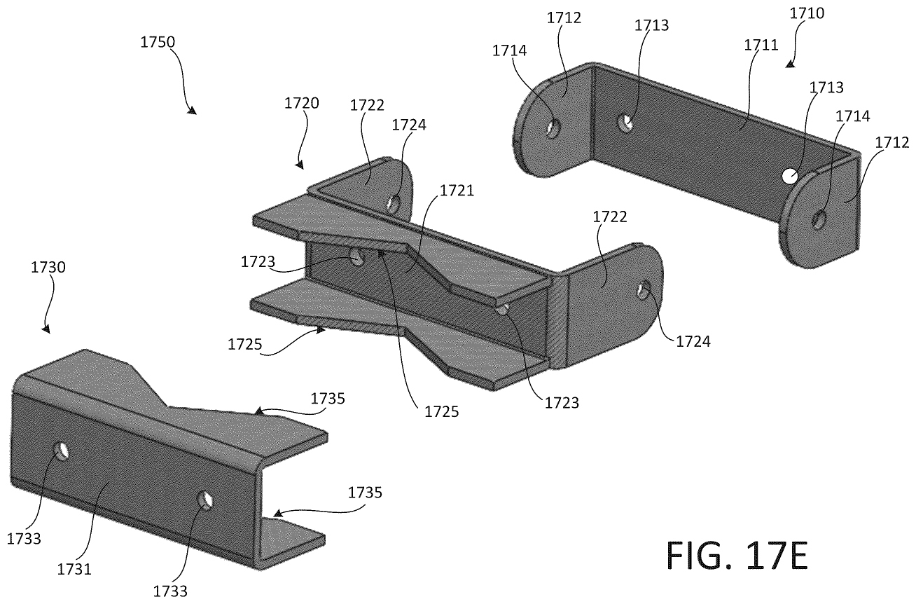

FIGS. 17A-17E illustrate an example component mounting assembly 1700 providing for the mounting of a component 1780 on a support structure 1790, such as, for example, a pole. In some examples, the component mounting assembly 1700 provides for the shielding of a component 1780 mounted on the support structure 1790. FIG. FIG. 17A is a first perspective view, and FIG. 17B is a second perspective view, of the example mounting assembly 1700 providing for the mounting of the component 1780 on the support structure 1790. FIG. 17C is an exploded view of the example mounting assembly 1700, component 1780, and support structure 1790. FIG. 17D is a perspective view of a bracket assembly 1750 of the example mounting assembly 1700, removed from the component 1780 and the support structure 1790. FIG. 17E is an exploded view of the example bracket assembly 1750 shown in FIG. 17D.

The example support structure 1790 in the form of a pole (for example, for use with a slim line telecommunications assembly) is shown in FIGS. 17A-17E, simply for purposes of discussion and illustration. The example component mounting assembly 1700 can be installed on other types of support structures such as, for example, the support structures described above including, for example, a frame portion coupled to a telecommunications tower, a lattice structure of a telecommunications tower, and other such arrangements of support structures.

In the example arrangement shown in FIGS. 17A-17E, the example component mounting assembly 1700 provides for the mounting of one component 1780 to the support structure 1790, simply for purposes of discussion and illustration. In some examples, more components can be similarly mounted to the support structure 1790 using a similar mounting structure. In the example arrangement shown in FIGS. 17A-17E, the example component mounting assembly 1700 includes a plurality of bracket assemblies 1750 (for example, a first bracket assembly 1750A and a second bracket assembly 1750B) mounting the component 1780 to the support structure 1790, simply for purposes of discussion and illustration. The principles described herein are applicable to component mounting assemblies including more, or fewer bracket assemblies for the mounting of a component on a structural support member.

In the example arrangement shown in FIGS. 17A-17E, each example bracket assembly 1750 includes a first bracket 1710 that is coupled to the component 1780, and a second bracket 1720 that is coupled between the first bracket 1710 and a third bracket 1730. The third bracket 1730 is coupled to the second bracket 1720 with the support structure 1790 (in the form of a rod) positioned therebetween, to couple the bracket assembly 1750, and the component 1780, to the support structure 1790.

In the example arrangement shown in FIGS. 17A-17E, the first bracket 1710 is a U-shaped, or C-shaped bracket, including a base wall 1711 and opposing side walls 1712 extending outward from lateral end portions of the base wall 1711, for example, towards the second bracket 1720. One or more openings 1713 are formed in the base wall 1711, to respectively receive one or more fasteners (not explicitly shown in FIGS. 17A-17E) for fastening the first bracket 1710 to the component 1780. At least one opening 1714 is formed in each of the side walls 1712 of the first bracket 1710, to receive fasteners for coupling the first bracket 1710 and the second bracket 1720. In some examples, the one or more fasteners fastening the first bracket 1710 to the component 1780 are made of a non-conductive material, or another material that does not generate PIM (including, for example, a carbon fiber composite material as discussed above), to further mitigate potential sources of PIM.

In the example arrangement shown in FIGS. 17A-17E, the second bracket 1720 includes a base wall 1721, and opposing side walls 1722 extending outward from lateral end portions of the base wall 1721, for example, towards the first bracket 1710. One or more openings 1723 are formed in the base wall 1721, to respectively receive one or more fasteners for fastening the second bracket 1720 to third bracket 1730. In some examples, the one or more fasteners fastening the second bracket 1720 to the third bracket 1730 are made of a non-conductive material, or another material that does not generate PIM (including, for example, a carbon fiber composite material as discussed above), to further mitigate potential sources of PIM. At least one opening 1724 is formed in each of the side walls 1722 of the second bracket 1720, to receive the fasteners for coupling the first bracket 1710 and the second bracket 1720 at the respective side walls 1712, 1722. The second bracket 1720 includes a coupling portion including mating surfaces 1725 that extend outward from upper and lower end portions of the base wall 1721, for example, toward the third bracket 1730, and configured to engage the support structure 1790. In some examples, a contour of each mating surface 1725 may be configured to provide for engagement with a variety of different support structures 1790 having different sizes and/or shapes and/or configurations and/or surface contours. In the example arrangement shown in FIGS. 17A-17E, each of the mating surfaces 1725 has an angular contour, to provide for surface contact and engagement between the mating surface 1725 and a mating surface of a variety of differently configured support structures 1790.

In the example arrangement shown in FIGS. 17A-17E, the third bracket 1730 includes a base wall 1731, with one or more openings 1733 formed in the base wall 1731 at positions corresponding to the one or more openings 1723 formed in the base wall 1721 of the second bracket 1720, to respectively receive one or more fasteners for fastening the third bracket 1730 to the second bracket 1720. The third bracket 1730 includes a coupling portion including mating surfaces 1735 that extend outward from upper and lower end portions of the base wall 1731, for example, toward the second bracket 1720, and configured to engage the support structure 1790. In some examples, a contour of each mating surface 1735 may be configured to provide for engagement with a variety of different support structures 1790 having different sizes and/or shapes and/or configurations and/or surface contours. In the example arrangement shown in FIGS. 17A-17E, each of the mating surfaces 1735 has an angular contour, to provide for surface contact and engagement between the mating surface 1735 and a mating surface of a variety of differently configured support structures 1790. When the fasteners are inserted through the openings 1733 in the base wall 1731 of the third bracket 1730 and into the corresponding openings 1723 in the base wall 1721 of the second bracket 1720, and tightened to securely fix the third bracket 1730 to the second bracket 1720, the mating surfaces 1725, 1735 of the second and third brackets 1720, 1730 engage the support structure 1790, to couple the bracket assembly 1750, and the component 1780, to the support structure 1790.

In some examples, the component mounting assembly 1700 includes a shielding member 1770. In the example arrangement shown in FIGS. 17A-17C, the shielding member 1770 is positioned between the support structure 1790 and a corresponding surface of the component 1780. In some examples, the shielding member 1770 is adhered to the surface of the component 1780. In some examples, the component 1780 and the shielding member 1770 are coupled to each other in other ways. In some examples, the shielding member 1770 is positioned proximate the surface of the component 1780, but not affixed directly to the component 1780. In some examples, the shielding member 1770 includes cutaway areas 1775 designed to accommodate component mounting hardware. The cutaway areas 1775 may be positioned and/or shaped and/or contoured to allow the shielding member 1770 to be positioned on the component 1780 without removing the component 1780 from the support structure 1790 and/or removing one or more of the bracket assemblies 1750. In some examples, the shielding member 1770 is made of a composite material, for example, a carbon fiber material, to shield the component 1780 from the effects of PIM. In the example shown in FIGS. 17A and 17B, the shielding member 1770 is a substantially planar panel, having a shape, or contour, corresponding to a mating or coupling surface of the component 1780, simply for purposes of discussion and illustration. The principles described herein are applicable to shielding members having different configurations.

In some examples, some, or all of the elements of the mounting assembly 1700, and in particular the bracket assemblies 1750, are made of a composite material. Fabricating the mounting assembly 1700 from composite materials avoids metal to metal connections, and produces a system that inherently provides for PIM mitigation. Removing metal to metal connections using composite elements may reduce or substantially eliminate the sources of PIM that may affect performance of the components 1780 coupled to the mounting assembly 1700. For example, the first bracket 1710 and/or the second bracket 1720 and/or the third bracket 1730 and/or the fasteners coupling the first bracket 1710 and the second bracket 1720 and the third bracket 1730 may be made of a composite material, to reduce or substantially eliminate generation of PIM due to interaction between and/or degradation of those elements of the mounting assembly 1700. In some examples, the support structure 1790 is made of a composite material, to further reduce or substantially eliminate generation of PIM due to interaction of the bracket assemblies 1750 with the support structure 1790. In some examples, the arrangement of the bracket assemblies 1750, and coupling of the multiple components 1780 to the support structure 1790 using multiple bracket assemblies 1750, may provide for shielding of the components 1780 from the effects of PIM. In some examples, the relative positioning of a plurality of components 1780 by a corresponding plurality of bracket assemblies 1750 in this manner may provide for shielding of the plurality of components 1780 from the effects of PIM while still allowing the plurality of components 1780 to be positioned relatively closely together. This may allow the plurality of components 1780 to transmit and receive signals without noise or interference due to PIM.

Reducing or substantially eliminating sources of PIM, and shielding of the plurality of components 1780, including for example, antennas, provided by the example mounting assembly 1700 described above allows the antennas to clearly and consistently transmit and receive radio frequency (RF) signals, thus maintaining the efficient and effective operation of the antennas mounted on a telecommunications tower, a slim line telecommunications pole, or other mounting structure. This allows the plurality of components 1780, for example, antennas to clearly and consistently transmit and receive radio frequency (RF) signals by reducing disturbances generated due to PIM in surrounding structure(s). This may also allow signals to be transmitted effectively over longer distances. This may allow for components such as antennas to be more densely arranged, either on new or existing support structures, while still clearly and consistently transmitting and receiving RF signals. The mounting assembly 1500 also allows components to have a fine-tuned angle of signal, providing for functionality with various antennas and site locations.

In the foregoing disclosure, it will be understood that when an element, such as a layer, a region, or a substrate, is referred to as being on, connected to, or coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A device, comprising:
a shielding member including a carbon fiber material, the shielding member being configured to be positioned proximate a component so as to shield the component from passive intermodulation (PIM) effects in an installation environment of the component;
wherein the shielding member comprises:
a panel portion configured to be coupled to a corresponding coupling surface of the component;
a first arm portion extending from a first lateral side portion of the panel portion, at an angle with respect to the panel portion, so as to shield a corresponding first lateral side portion of the component; and
a second arm portion extending from a second lateral side portion of the panel portion, at an angle with respect to the panel portion, so as to shield a corresponding second lateral side portion of the component.

2. The device of claim 1, wherein a contour of the panel portion, the first arm portion, and the second arm portion is at least partially conformal to a contour of the component, such that the panel portion, the first arm portion, and the second arm portion at least partially surround the component.

3. The device of claim 1, further comprising:
a plurality of openings formed in the panel portion and configured to receive coupling portions of the component therethrough.

4. The device of claim 1, wherein the component is a telecommunications component including at least one antenna configured to be mounted on a telecommunications tower, a telecommunications pole, or a mounting surface of a building.

5. A mounting system, comprising:
a mounting device configured to mount a telecommunications component on a support structure; and
a shielding member coupled to a coupling portion of the component, positioned between the component and the mounting device, wherein the shielding member is configured to shield the component from passive intermodulation (PIM) effects in an installation environment of the mounting device.

6. The mounting system of claim 5, wherein the shielding member comprises:
a panel portion configured to be coupled to a corresponding coupling surface of the component;
a first arm portion extending from a first lateral side portion of the panel portion, at an angle with respect to the panel portion, so as to shield a corresponding first lateral side portion of the component; and
a second arm portion extending from a second lateral side portion of the panel portion, at an angle with respect to the panel portion, such that a contour of the panel portion, the first arm portion, and the second arm portion is at least partially conformal to a contour of the component, and the first arm portion, and the second arm portion at least partially surround the component.

7. The mounting system of claim 5, wherein the mounting device and the shielding member are made of a carbon fiber composite material including a carbon fiber material impregnated in a resin material.

8. The mounting system of claim 5, wherein the mounting device includes a bracket assembly, comprising:
a first bracket configured to be coupled to the component; and
a second bracket configured to be coupled between the first bracket and the support structure;
wherein:
the first bracket includes a first side wall and a second side wall each including a first opening and a second opening, and the second bracket includes a first side wall and a second side wall each including a first opening and a second opening formed as an arcuate slot;
fasteners are coupled in the first openings formed in the first and second side walls of the first and second brackets to couple the first and second side walls of the first and second brackets; and
fasteners are slidably received in the second openings in the first and second side walls of the second bracket, and coupled into the second openings in the first and second side walls of the first bracket, such that an angular orientation of the component relative to the support structure is adjustable based on a position of the fastener in the second openings in the first and second side walls of the second bracket.

9. The mounting system of claim 5, wherein the mounting device includes a bracket assembly, comprising:
a first bracket configured to be coupled to the component; and
a second bracket coupling the first bracket to a third bracket, wherein the support structure is received between the second bracket and the third bracket;
wherein:
the second bracket includes first and second mating surfaces extending outward from upper and lower end portions of a base wall, toward the third bracket;
the third bracket includes first and second mating surfaces extending outward from upper and lower end portions of a base wall, toward the second bracket, with the support structure received between the respective mating surfaces of the first and second brackets; and
fasteners coupling the base wall of the third bracket and the base wall of the second bracket provide for adjustable coupling of the second and third brackets on the support structure.

10. A device, comprising:
a shielding member including a carbon fiber material, the shielding member being configured to be positioned proximate a component so as to shield the component from passive intermodulation (PIM) effects in an installation environment of the component;
wherein the shielding member comprises a plurality of shielding members configured to shield a respective plurality of components from PIM effects, each of the plurality of shielding members comprising:
a panel portion configured to be coupled to a coupling surface of a component of the plurality of components; and
at least one arm portion extending outward from a lateral side portion of the panel portion, at an angle with respect to the panel portion, so as to be positioned between the component and an adjacent component of the plurality of components.

11. The device of claim 10, wherein the at least one arm portion includes:
a first arm portion extending outward from a first lateral side portion of the panel portion, at an angle with respect to the panel portion, so as to be positioned between the component and a first adjacent component of the plurality of components; and
a second arm portion extending outward from a second lateral side portion of the panel portion opposite the first lateral side portion thereof, at an angle with respect to the panel portion, so as to be positioned between the component and a second adjacent component of the plurality of components.

12. The device of claim 10, wherein the device further comprises:
a first end plate;
a second end plate; and
a rod extending through the first end plate and the second end plate;
wherein the plurality of shielding members and the plurality of components are positioned surrounding the rod, between the first end plate and the second end plate; and
wherein the plurality of shielding members, the first end plate, and the second end plate define a plurality of receiving spaces respectively receiving the plurality of components.

13. The device of claim 12, wherein the first end plate, the second end plate, and the plurality of shielding members are made of a carbon fiber composite material including a carbon fiber material impregnated in a resin material.

14. A device, comprising:
a shielding member including a carbon fiber material, the shielding member being configured to be positioned proximate a component so as to shield the component from passive intermodulation (PIM) effects in an installation environment of the component;
wherein the shielding member comprises:
a panel portion configured to be coupled to a coupling surface of the component; and
at least one portion configured to accommodate a bracket assembly coupling the component to a support structure.

15. The device of claim 14, wherein the bracket assembly comprises:
a first bracket configured to be coupled to the coupling surface of the component; and
a second bracket coupling the first bracket to a third bracket, wherein the second bracket and the third bracket are configured to couple the component to the support structure.

16. The device of claim 15,
wherein the first bracket includes:
a first base wall configured to be coupled to the component; and
first and second side walls extending outward from opposite end portions of the first base wall, toward the second bracket; and
wherein the second bracket includes:
a second base wall;
first and second side walls extending outward from opposite end portions of the second base wall, toward the first bracket, wherein the first and second side walls of the second bracket are coupled to the first and second side walls of the first bracket; and
first and second mating surfaces extending outward from upper and lower end portions of the second base wall, toward the third bracket; and
wherein the third bracket includes:
a third base wall; and
first and second mating surfaces extending outward from upper and lower end portions of the third base wall, toward the second bracket;
wherein the third base wall is adjustably couplable to the second base wall to adjust a distance between the first and second mating surfaces of the second bracket and the first and second mating surfaces of the third bracket, to couple the support structure between the second bracket and the third bracket.

17. The device of claim 14, wherein the shielding member and the bracket assembly are made of a carbon fiber composite material including a carbon fiber material impregnated in a resin material.

18. The device of claim 14, wherein the bracket assembly comprises:
a first bracket configured to be coupled to the coupling surface of the component; and
a second bracket configured to be coupled between the first bracket and the support structure;
wherein the first bracket includes:
a first base wall configured to be coupled to the component; and
first and second side walls extending outward from opposite end portions of the first base wall, toward the second bracket; and
wherein the second bracket includes:
a second base wall;
first and second side walls extending outward from opposite end portions of the second base wall, toward the first bracket; and
first and second flange portions extending outward from the second base wall, the first and second flange portions being configured to be coupled to a second bracket of an adjacent bracket assembly coupling another component to the support structure, and to engage the support structure so as to couple the component to the support structure.

19. The device of claim 18, wherein:
the first bracket includes a first opening and a second opening in each of the first and second side walls of the first bracket;
the second bracket includes a first opening in each of the first and second side walls of the second bracket, at positions corresponding to the first opening in each of the first and second side walls of the first bracket, so as to receive fasteners therethrough; and
the second bracket includes a second opening, defined by an arcuate slot, formed in each of the first and second side walls of the second bracket, wherein fasteners are slidably received in the second openings in the first and second side walls of the second bracket, and coupled into the second openings in the first and second side walls of the first bracket, such that an angular orientation of the component relative to the support structure is adjustable based on a position of the fastener in the second openings in the first and second side walls of the second bracket.

20. The device of claim 14, wherein the bracket assembly comprises:
a central bracket coupled to the support structure;
a first arm rotatably coupled to a first end portion of the central bracket and configured to rotatably couple a first component to the support structure; and
a second arm rotatably coupled to a second end portion of the central bracket and configured to rotatably couple a second component to the support structure, the first arm and the second arm each including:
a body portion;
a slot extending in a longitudinal direction of the body portion, the slot being configured to receive at least one fastener therethrough for coupling the body portion to respective component; and
leg portions extending outward from upper and lower side portions of the body portion and configured to contact the respective component.
